(19) United States
(12) Patent Application Publication
(10) Pub. No.: US 2024/0074242 A1
(43) Pub. Date: Feb. 29, 2024

(54) DISPLAY APPARATUS

(71) Applicant: Samsung Display Co., Ltd., Yongin-si (KR)

(72) Inventors: Donghyeon Jang, Yongin-si (KR); Wonse Lee, Yongin-si (KR); Yujin Jeon, Yongin-si (KR)

(21) Appl. No.: 18/347,496

(22) Filed: Jul. 5, 2023

(30) Foreign Application Priority Data
Aug. 31, 2022 (KR) 10-2022-0110319

(51) Int. Cl. H10K 59/122; G09G 3/3233; H10K 59/131

(52) U.S. Cl. CPC H10K 59/122; G09G 3/3233; H10K 59/131; G09G 2300/0842

(57) ABSTRACT

A display apparatus includes: a substrate including: a first auxiliary pixel area; a second auxiliary pixel area adjacent to the first auxiliary pixel area; a third auxiliary pixel area adjacent to the first auxiliary pixel area; and a transmission area between the first auxiliary pixel area and the second auxiliary pixel area, and between the first auxiliary pixel area and the third auxiliary pixel area; a pixel-defining layer including: a first auxiliary opening in the first auxiliary pixel area; a second auxiliary opening in the second auxiliary pixel area; and a third auxiliary opening in the third auxiliary pixel area; an auxiliary connection wiring under the first, second, or third auxiliary pixel electrodes, and extending from the first auxiliary pixel area, the second auxiliary pixel area, or the third auxiliary pixel area to the transmission area; and an organic layer at the transmission area.

### CROSS-REFERENCE TO RELATED APPLICATION

This application claims priority to and the benefit of Korean Patent Application No. 10-2022-0110319, filed on Aug. 31, 2022, in the Korean Intellectual Property Office, the entire disclosure of which is incorporated by reference herein.

### BACKGROUND

### 1. Field

Aspects of one or more embodiments of the present disclosure relate to a display apparatus, and more particularly, to a display apparatus having high transmittance.

### 2. Description of the Related Art

Recently, usages of display apparatuses have diversified. Accordingly, various functions have been applied or linked to the display apparatuses. To perform such functions, a display panel included in a display apparatus may include an area having high transmittance of light or sound. In order for the display apparatus to perform such functions without reducing an area in which an image is displayed, the display panel may include an area having high transmittance of light or sound, and in which an image is displayed.

The above information disclosed in this Background section is for enhancement of understanding of the background of the present disclosure, and therefore, it may contain information that does not constitute prior art.

### SUMMARY

In a process of transmitting an electrical signal to a display element of a display apparatus, the electrical signal may not be effectively transmitted to the display element.

One or more embodiments of the present disclosure are directed to a display apparatus having high transmittance, and in which an electrical signal may be effectively transmitted to a display element. However, the present disclosure is not limited thereto.

Additional aspects and features of the present disclosure will be set forth, in part, in the description that follows, and in part, will be apparent from the description, or may be learned by practicing one or more of the presented embodiments of the present disclosure.

According to one or more embodiments of the present disclosure, a display apparatus includes: a substrate including: a first auxiliary pixel area; a second auxiliary pixel area adjacent to the first auxiliary pixel area in a first direction; a third auxiliary pixel area adjacent to the first auxiliary pixel area in a second direction crossing the first direction; and a transmission area between the first auxiliary pixel area and the second auxiliary pixel area, and between the first auxiliary pixel area and the third auxiliary pixel area; a pixel-defining layer including: a first auxiliary opening in the first auxiliary pixel area to expose a central portion of a first auxiliary pixel electrode under the pixel-defining layer; a second auxiliary opening in the second auxiliary pixel area to expose a central portion of a second auxiliary pixel electrode under the pixel-defining layer; and a third auxiliary opening in the third auxiliary pixel area to expose a central portion of a third auxiliary pixel electrode under the pixel-defining layer; an auxiliary connection wiring under the first auxiliary pixel electrode, the second auxiliary pixel electrode, or the third auxiliary pixel electrode, and extending from the first auxiliary pixel area, the second auxiliary pixel area, or the third auxiliary pixel area to the transmission area; and an organic layer at the transmission area.

In an embodiment, a portion of the auxiliary connection wiring may be located at the transmission area, and the organic layer may be on the portion of the auxiliary connection wiring located at the transmission area.

In an embodiment, the organic layer may cover the portion of the auxiliary connection wiring located at the transmission area.

In an embodiment, the pixel-defining layer may include a light-blocking material.

In an embodiment, the organic layer may include a transparent organic insulating material, and may not include a light-blocking material.

In an embodiment, the display apparatus may further include: an opposite electrode on the first auxiliary pixel electrode, the second auxiliary pixel electrode, and the third auxiliary pixel electrode; a first common layer between the first auxiliary pixel electrode and a first auxiliary emission layer, between the second auxiliary pixel electrode and a second auxiliary emission layer, and between the third auxiliary pixel electrode and a third auxiliary emission layer; and a second common layer between the first auxiliary emission layer and the opposite electrode, between the second auxiliary emission layer and the opposite electrode, and between the third auxiliary emission layer and the opposite electrode.

In an embodiment, a portion of the opposite electrode, a portion of the first common layer, and a portion of the second common layer may be located at the transmission area.

In an embodiment, the portion of the opposite electrode located at the transmission area may be on the organic layer, and the portion of the first common layer located at the transmission area and the portion of the second common layer located at the transmission area may be located between the organic layer and the opposite electrode.

In an embodiment, the transmission area may surround the first auxiliary pixel area, the second auxiliary pixel area, and the third auxiliary pixel area.

In an embodiment, the auxiliary connection wiring may include a first auxiliary connection wiring, a second auxiliary connection wiring, and a third auxiliary connection wiring; the first auxiliary pixel area may include a plurality of first auxiliary pixel areas; the second auxiliary pixel area may include a plurality of second auxiliary pixel areas; the third auxiliary pixel area may include a plurality of third auxiliary pixel areas; the first auxiliary connection wiring may electrically connect a plurality of first auxiliary pixel electrodes located at the plurality of first auxiliary pixel areas to each other; the second auxiliary connection wiring may electrically connect a plurality of second auxiliary pixel electrodes located at the plurality of second auxiliary pixel areas to each other; and the third auxiliary connection wiring may electrically connect a plurality of third auxiliary pixel electrodes located at the plurality of third auxiliary pixel areas to each other.

In an embodiment, the display apparatus may further include a component overlapping with the first auxiliary pixel area, the second auxiliary pixel area, the third auxiliary pixel area, and the transmission area.

According to one or more embodiments of the present disclosure, a display apparatus includes: a substrate including a plurality of first auxiliary pixel areas, and a transmission area between the plurality of first auxiliary pixel areas; a pixel-defining layer having first auxiliary openings located at the plurality of first auxiliary pixel areas to each other to expose central portions of first auxiliary pixel electrodes under the pixel-defining layer; a first auxiliary connection wiring under the first auxiliary pixel electrodes, and extending to the transmission area; and an organic layer at the transmission area.

In an embodiment, a portion of the first auxiliary connection wiring may be located at the transmission area, and the organic layer may be on the portion of the first auxiliary connection wiring located at the transmission area.

In an embodiment, the organic layer may cover the portion of the first auxiliary connection wiring located at the transmission area.

In an embodiment, the pixel-defining layer may include a light-blocking material.

In an embodiment, the organic layer may include a transparent organic insulating material, and may not include a light-blocking material.

In an embodiment, the display apparatus may further include: an opposite electrode on the first auxiliary pixel electrodes; a first common layer between the first auxiliary pixel electrodes and first auxiliary emission layers; and a second common layer between the first auxiliary emission layers and the opposite electrode.

In an embodiment, a portion of the opposite electrode, a portion of the first common layer, and a portion of the second common layer may be located at the transmission area.

In an embodiment, the portion of the opposite electrode located at the transmission area may be on the organic layer, and the portion of the first common layer located at the transmission area and the portion of the second common layer located at the transmission area may be between the organic layer and the opposite electrode.

In an embodiment, the transmission area may surround each of the plurality of first auxiliary pixel areas.

In an embodiment, the first auxiliary connection wiring may electrically connect the first auxiliary pixel electrodes at the plurality of first auxiliary pixel areas to each other.

In an embodiment, the display apparatus may further include a component overlapping with the plurality of first auxiliary pixel areas and the transmission area.

The above and other aspects and features from those described above will become more apparent from the detailed description of the present disclosure, the drawings, the claims, and their equivalents.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIGS. 1 and 2 are schematic perspective views of a display apparatus according to one or more embodiments;

FIG. 3 is a schematic cross-sectional view of a display apparatus according to an embodiment;

FIG. 4 is a schematic equivalent circuit diagram of a pixel circuit electrically connected to a display element, according to an embodiment;

FIGS. 5 and 6 are schematic plan views of a display panel of a display apparatus according to one or more embodiments;

FIG. 7 is a schematic cross-sectional view of a portion of a display panel of a display apparatus according to an embodiment;

FIG. 8 is a schematic plan view of a portion of a display panel of a display apparatus according to an embodiment;

FIG. 9 is a schematic cross-sectional view of a portion of a display panel of a display apparatus according to an embodiment;

FIG. 10 is a schematic cross-sectional view of a portion of a display panel of a display apparatus according to an embodiment; and

FIGS. 11A-11D are schematic cross-sectional views showing parts of a manufacturing process of the display panel illustrated in FIG. 8.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

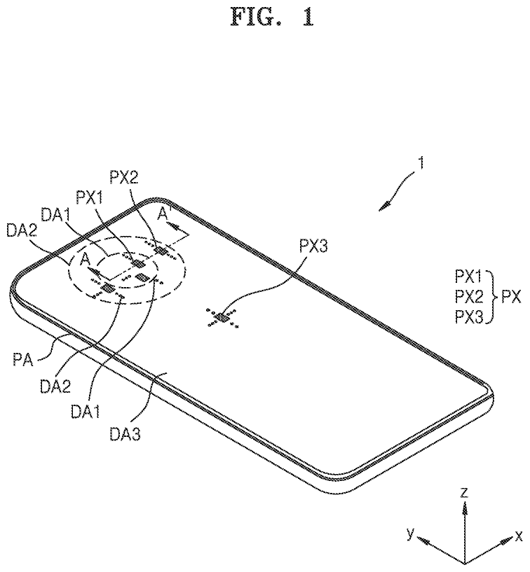

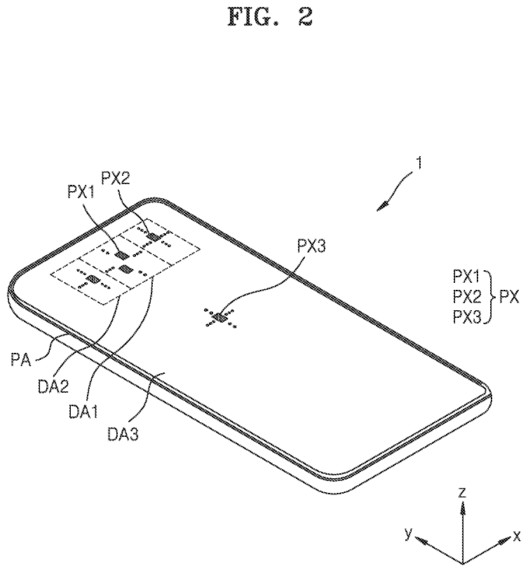

FIGS. 1 and 2 are schematic perspective views of a display apparatus 1 according to one or more embodiments. Referring to FIGS. 1 and 2, the display apparatus 1 may display an image. The display apparatus 1 may include a pixel PX, and the pixel PX may be defined as an area in which a display element emits light. In an embodiment, a plurality of pixels PX may be provided in the display apparatus 1. Each of the plurality of pixels PX may emit light and display an image. In an embodiment, the plurality of pixels PX may include an auxiliary pixel PX1, an intermediate pixel PX2, and a main pixel PX3. In an embodiment, a plurality of auxiliary pixels PX1, a plurality of intermediate pixels PX2, and a plurality of main pixels PX3 may be provided. The plurality of auxiliary pixels PX1, the plurality of intermediate pixels PX2, and the plurality of main pixels PX3 may display a single image (e.g., may display an image together), or may each display an independent image.

The display apparatus 1 may include an auxiliary display area DA1, an intermediate display area DA2, a main display area DA3, and a peripheral area PA. The pixel PX may be arranged at (e.g., in or on) the auxiliary display area DA1, the intermediate display area DA2, and the main display area DA3. Accordingly, the auxiliary display area DA1, the intermediate display area DA2, and the main display area DA3 may be areas in which images are displayed. In this regard, the auxiliary pixel PX1 may be arranged at (e.g., in or on) the auxiliary display area DA1, the intermediate pixel PX2 may be arranged at (e.g., in or on) the intermediate display area DA2, and the main pixel PX3 may be arranged at (e.g., in or on) the main display area DA3. The pixel PX may not be arranged at (e.g., in or on) the peripheral area PA. Accordingly, the peripheral area PA may be a non-display area in which no image is displayed.

At least one of the auxiliary display area DA1 or the intermediate display area DA2 may be an area overlapping with a component, and concurrently, may be an area at (e.g., in or on) which the pixel PX is arranged. For example, the auxiliary display area DA1 may be an area overlapping with the component, and concurrently, may be an area at (e.g., in or on) which the pixel PX is arranged. As another example, the auxiliary display area DA1 and the intermediate display area DA2 may both be an area overlapping with the component, and concurrently, may be an area at (e.g., in or on) which the pixel PX is arranged. In more detail, the auxiliary display area DA1 and the intermediate display area DA2 may be areas at (e.g., in or on) which the pixel PX is arranged. In an embodiment, the auxiliary pixel PX1 may be arranged at (e.g., in or on) the auxiliary display area DA1, and the intermediate pixel PX2 may be arranged at (e.g., in or on) the intermediate display area DA2. Accordingly, the auxiliary display area DA1 and the intermediate display area DA2 may be areas in which images are displayed.

At least one of the auxiliary display area DA1 or the intermediate display area DA2 may overlap with the component. Accordingly, the auxiliary display area DA1 and/or the intermediate display area DA2 of the display apparatus 1 may have high light transmittance or high acoustic transmittance. For example, light transmittance of the display apparatus 1 in the auxiliary display area DA1 and/or the intermediate display area DA2 may be about 10% or more, about 25% or more, about 40% or more, about 50% or more, about 85% or more, or about 90% or more. In an embodiment, the light transmittance of the display apparatus 1 in the auxiliary display area DA1 may be higher than the light transmittance of the display apparatus 1 in the intermediate display area DA2.

In an embodiment, the display apparatus 1 may include at least one auxiliary display area DA1. For example, the display apparatus 1 may include one auxiliary display area DA1, or a plurality of auxiliary display areas DA1.

In an embodiment, the intermediate display area DA2 may at least partially surround (e.g., around a periphery of) the auxiliary display area DA1. For example, as shown in FIG. 1, the intermediate display area DA2 may entirely surround (e.g., around a periphery of) the auxiliary display area DA1. As another example, as shown in FIG. 2, the intermediate display area DA2 may be arranged on one or more sides of the auxiliary display area DA1. For example, the auxiliary display area DA1 and the intermediate display area DA2 may be arranged side by side with each other in a first direction (e.g., an x-direction or a −x-direction). As another example, the auxiliary display area DA1 and the intermediate display area DA2 may be arranged side by side with each other in a second direction (e.g., a y-direction or a −y-direction). In an embodiment, as shown in FIG. 2, the intermediate display area DA2 may be arranged on opposite sides of the auxiliary display area DA1.

In an embodiment, the auxiliary display area DA1 and the intermediate display area DA2 may be arranged on an upper side of the display apparatus 1. However, the present disclosure is not limited thereto. The auxiliary display area DA1 and the intermediate display area DA2 may be arranged on a lower side, a right side, and/or a left side of the display apparatus 1.

In an embodiment, at least one of the auxiliary display area DA1 or the intermediate display area DA2 may have various suitable shapes in a plan view (e.g., in an x-y plane), for example, such as a polygon including a quadrangle, a star, or a diamond, a circle, an ellipse, or the like. FIG. 1 shows that the auxiliary display area DA1 and the intermediate display area DA2 each have a circular shape, and FIG. 2 shows that the auxiliary display area DA1 and the intermediate display area DA2 each have a quadrangular shape.

The main display area DA3 may at least partially surround (e.g., around a periphery of) the auxiliary display area DA1 and/or the intermediate display area DA2. In an embodiment, as shown in FIG. 1, the intermediate display area DA2 may entirely surround (e.g., around a periphery of) the auxiliary display area DA1, and the main display area DA3 may entirely surround (e.g., around a periphery of) the intermediate display area DA2. As another example, as shown in FIG. 2, the main display area DA3 may entirely surround (e.g., around a periphery of) the auxiliary display area DA1 and/or the intermediate display area DA2. The resolution of the display apparatus 1 in the main display area DA3 may be higher than or equal to the resolution of the display apparatus 1 in the auxiliary display area DA1.

The peripheral area PA may at least partially surround (e.g., around a periphery of) the main display area DA3. In an embodiment, the peripheral area PA may entirely surround (e.g., around a periphery of) the main display area DA3. As described above, the pixel PX may not be arranged at (e.g., in or on) the peripheral area PA.

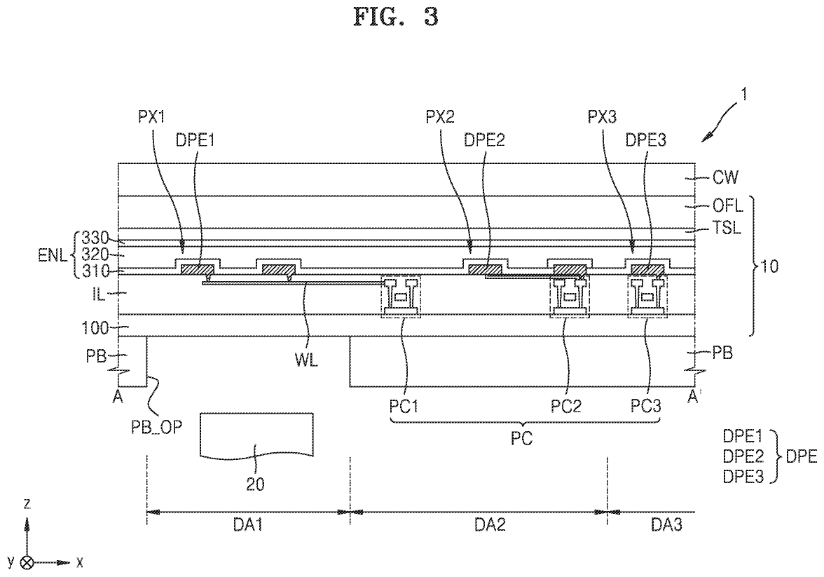

FIG. 3 is a schematic cross-sectional view of the display apparatus 1 according to an embodiment. In more detail, FIG. 3 is a schematic cross-sectional view of the display apparatus 1 taken along the line A-A′ of FIG. 1.

Referring to FIG. 3, the display apparatus 1 may include a display panel 10, a panel protection member PB, a component 20, and a cover window CW. The display panel 10 may include a substrate 100, an insulating layer IL, a pixel circuit PC, a display element DPE, an encapsulation layer ENL, a touch sensor layer TSL, and an optical functional layer OFL.

The display apparatus 1 may include the auxiliary display area DA1, the intermediate display area DA2, the main display area DA3, and the peripheral area PA. In other words, because the display apparatus 1 includes the display panel 10, the display panel 10 may include the auxiliary display area DA1, the intermediate display area DA2, the main display area DA3, and the peripheral area PA. Further, because the display panel 10 includes the substrate 100, in other words, the substrate 100 may include the auxiliary display area DA1, the intermediate display area DA2, the main display area DA3, and the peripheral area PA. In other words, the auxiliary display area DA1, the intermediate display area DA2, the main display area DA3, and the peripheral area PA may be defined at (e.g., in or on) the substrate 100. Hereinafter, a case in which the substrate 100 includes the auxiliary display area DA1, the intermediate display area DA2, the main display area DA3, and the peripheral area PA is mainly described in more detail.

The substrate 100 may include an insulating material, such as glass, quartz, or polymer resin. The substrate 100 may be a rigid substrate, or a flexible substrate that is bendable, foldable, or rollable.

The insulating layer IL may be disposed on the substrate 100. The insulating layer IL may insulate components of the display panel 10. The insulating layer IL may include at least one of an organic material or an inorganic material.

The pixel circuit PC may be arranged at (e.g., in or on) the insulating layer IL. The pixel circuit PC may be electrically connected to the display element DPE to drive the display element DPE. In an embodiment, a plurality of pixel circuits PC may be provided. The plurality of pixel circuits PC may include an auxiliary pixel circuit PC1, an intermediate pixel circuit PC2, and a main pixel circuit PC3. The auxiliary pixel circuit PC1 and the intermediate pixel circuit PC2 may be arranged at (e.g., in or on) the intermediate display area DA2. The main pixel circuit PC3 may be arranged at (e.g., in or on) the main display area DA3. In an embodiment, the pixel circuit PC may not be arranged at (e.g., in or on) the auxiliary display area DA1. Accordingly, the transmittance (e.g., the light transmittance) of the display panel 10 in the auxiliary display area DA1 may be relatively higher than the transmittances of the display panel in the intermediate display area DA2 and the main display area DA3.

The display element DPE may be disposed on the insulating layer IL. In an embodiment, the display element DPE may be an organic light-emitting diode including an organic emission layer. In another embodiment, the display element DPE may be a light-emitting diode including an inorganic emission layer. The size of the light-emitting diode may be on a micro scale or a nano scale. For example, the light-emitting diode may be a micro light-emitting diode. In another embodiment, the light-emitting diode may be a nanorod light-emitting diode. The nanorod light-emitting diode may include gallium nitride (GaN). In an embodiment, a color conversion layer may be disposed on the nanorod light-emitting diode, and the color conversion layer may include quantum dots. In another embodiment, the display element DPE may be a quantum dot light-emitting diode including quantum dots. Hereinafter, for convenience, a case in which the display element DPE is an organic light-emitting diode is mainly described in more detail.

In an embodiment, a plurality of display elements DPE may be provided. The plurality of display elements DPE may include an auxiliary display element DPE1, an intermediate display element DPE2, and a main display element DPE3. The auxiliary display element DPE1 may be arranged at (e.g., in or on) the auxiliary display area DA1. A plurality of auxiliary display elements DPE1 may be provided. In an embodiment, the plurality of auxiliary display elements DPE1 may be electrically connected to one auxiliary pixel circuit PC1 that is arranged at (e.g., in or on) the intermediate display area DA2. The auxiliary pixel circuit PC1 may include at least one thin-film transistor, and may control a light emission of the auxiliary display element DPE1. The auxiliary display element DPE1 may emit light through an emission area, and the emission area may be defined as the auxiliary pixel PX1. In other words, the auxiliary pixel PX1 may be implemented by the light emission of the auxiliary display element DPE1. Accordingly, because the plurality of auxiliary display elements DPE1 may emit light by using one auxiliary pixel circuit PC1, the transmittance of the auxiliary display area DA1 may be improved.

The one auxiliary pixel circuit PC1 arranged at (e.g., in or on) the intermediate display area DA2 may be electrically connected to the plurality of auxiliary display elements DPE1 arranged at (e.g., in or on) the auxiliary display area DA1 through a wiring WL. The wiring WL may extend from the intermediate display area DA2 to the auxiliary display area DA1. Accordingly, the wiring WL may be arranged at (e.g., in or on) the auxiliary display area DA1 and the intermediate display area DA2.

The intermediate display element DPE2 may be arranged at (e.g., in or on) the intermediate display area DA2. A plurality of intermediate display elements DPE2 may be provided. The plurality of intermediate display elements DPE2 may be electrically connected to one intermediate pixel circuit PC2 that is arranged at (e.g., in or on) the intermediate display area DA2. The intermediate pixel circuit PC2 may include at least one thin-film transistor, and may control a light emission of the intermediate display element DPE2. The intermediate display element DPE2 may emit light through an emission area, and the emission area may be defined as the intermediate pixel PX2. In other words, the intermediate pixel PX2 may be implemented by the light emission of the intermediate display element DPE2. Accordingly, the plurality of intermediate display elements DPE2 may emit light by using one intermediate pixel circuit PC2.

The main display element DPE3 may be arranged at (e.g., in or on) the main display area DA3. The main display element DPE3 may be electrically connected to the main pixel circuit PC3 that is arranged at (e.g., in or on) the main display area DA3. The main pixel circuit PC3 may include at least one thin-film transistor. The main pixel circuit PC3 may control a light emission of the main display element DPE3. The main display element DPE3 may emit light through an emission area, and the emission area may be defined as the main pixel PX3. In other words, the main pixel PX3 may be implemented by the light emission of the main display element DPE3.

The encapsulation layer ENL may cover the display element DPE. In an embodiment, the encapsulation layer ENL may include at least one inorganic encapsulation layer, and at least one organic encapsulation layer. The at least one inorganic encapsulation layer may include at least one inorganic material selected from among aluminum oxide (Al₂O₃), titanium oxide (TiO₂), tantalum oxide (Ta₂O₅), zinc oxide (ZnO), silicon oxide (SiO_{X}), silicon nitride (SiN_{X}), and silicon oxynitride (SiO_{X}N_{Y}). The at least one organic encapsulation layer may include a polymer-based material. The polymer-based material may include acrylic resin, epoxy-based resin, polyimide, polyethylene, and/or the like. In an embodiment, the at least one organic encapsulation layer may include acrylate.

In an embodiment, the encapsulation layer ENL may include a first inorganic encapsulation layer 310, an organic encapsulation layer 320, and a second inorganic encapsulation layer 330 that are sequentially stacked on one another. The first inorganic encapsulation layer 310 and the second inorganic encapsulation layer 330 may prevent or reduce penetration of foreign substances, such as moisture, into the organic encapsulation layer 320 and/or the display element DPE.

In another embodiment, the encapsulation layer ENL may have a structure in which the substrate 100 and a sealing substrate, which is a transparent member, are coupled to (e.g., connected to or attached to) each other by a sealing member, such that an inner space between the substrate 100 and the sealing substrate is sealed. In this regard, a desiccant or a filler may be provided in the inner space. The sealing member may be a sealant. In another embodiment, the sealing member may include a material that is cured by a laser. For example, the sealing member may be frit. In more detail, the sealing member may include an organic sealant, such as a urethane-based resin, an epoxy-based resin, or an acrylic resin, or an inorganic sealant, such as silicone. As the urethane-based resin, for example, urethane acrylate and/or the like may be used. As the acrylic resin, for example, butyl acrylate, ethylhexyl acrylate, and/or the like may be used. The sealing member may include a suitable material that is cured by heat.

The touch sensor layer TSL may obtain coordinate information according to an external input, for example, such as a touch event. The touch sensor layer TSL may include a touch electrode, and touch wirings connected to the touch electrode. The touch sensor layer TSL may sense the external input by using a self-capacitance method or a mutual capacitance method.

The touch sensor layer TSL may be disposed on the encapsulation layer ENL. In an embodiment, the touch sensor layer TSL may be disposed directly on the encapsulation layer ENL. In this case, an adhesive layer, such as an optically clear adhesive, may not be arranged between the touch sensor layer TSL and the encapsulation layer ENL. As another example, the touch sensor layer TSL may be separately formed on a touch substrate, and then coupled to (e.g., connected to or attached to) the encapsulation layer ENL through an adhesive layer, such as an optically clear adhesive.

The optical functional layer OFL may include an anti-reflection layer. The anti-reflection layer may reduce a reflectance of light (e.g., external light) incident from the outside toward the display apparatus 1. In an embodiment, the optical functional layer OFL may be a polarizing film. In another embodiment, the optical functional layer OFL may be a filter plate including a black matrix and color filters.

The cover window CW may be disposed on the display panel 10. The cover window CW may protect the display panel 10. The cover window CW may include at least one of glass, sapphire, or plastic. The cover window CW may include (e.g., may be), for example, ultra-thin glass (UTG) or colorless polyimide (CPI).

The panel protection member PB may be disposed under the substrate 100. The panel protection member PB may support and protect the substrate 100. In an embodiment, an opening PB_OP overlapping with the auxiliary display area DA1 may be defined in the panel protection member PB. In other words, the panel protection member PB may include the opening PB_OP overlapping with the auxiliary display area DA1. In an embodiment, the opening PB_OP of the panel protection member PB may overlap with the auxiliary display area DA1 and the intermediate display area DA2. The panel protection member PB may include polyethylene terephthalate or polyimide.

The component 20 may be disposed under the display panel 10. In an embodiment, the component 20 may be arranged opposite to the cover window CW, with the display panel 10 therebetween. In an embodiment, the component 20 may overlap with the auxiliary display area DA1. In another embodiment, the component 20 may overlap with the auxiliary display area DA1 and the intermediate display area DA2.

The component 20 may be a camera that uses infrared or visible light, and may include an imaging device. As another example, the component 20 may be a solar battery, a flash, an illuminance sensor, a proximity sensor, or an iris sensor. As another example, the component 20 may have a function for receiving sound. As described above, the pixel circuit PC may not be arranged at (e.g., in or on) the auxiliary display area DA1 under which the component 20 is disposed, such that limitations in or interference with the functionality of the component 20 may be prevented or reduced. In other words, the auxiliary pixel circuit PC1 that drives the auxiliary display element DPE1 arranged at (e.g., in or on) the auxiliary display area DA1 may not be arranged at (e.g., in or on) the auxiliary display area DA1, and may be arranged at (e.g., in or on) the intermediate display area DA2. Accordingly, the transmittance (e.g., the light transmittance) of the display panel 10 in the auxiliary display area DA1 may be higher than the transmittance (e.g., the light transmittance) of the display panel 10 in the intermediate display area DA2.

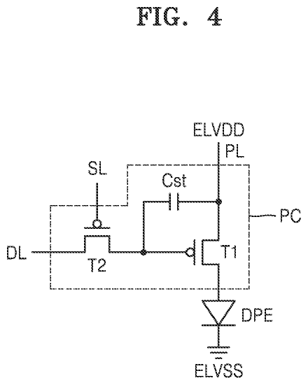

FIG. 4 is a schematic equivalent circuit diagram of the pixel circuit PC electrically connected to the display element DPE, according to an embodiment. Referring to FIG. 4, the pixel circuit PC may include a driving thin-film transistor T1, a switching thin-film transistor T2, and a storage capacitor Cst.

The switching thin-film transistor T2 may be electrically connected to a scan line SL and a data line DL, and may be configured to transmit a data signal (e.g., a data voltage) input from the data line DL to the driving thin-film transistor T1, based on a scan signal (e.g., a switching voltage) input from the scan line SL. The storage capacitor Cst may be electrically connected to the switching thin-film transistor T2 and a driving voltage line PL, and may be configured to store a voltage corresponding to a difference between a voltage received from the switching thin-film transistor T2 and a driving voltage ELVDD supplied to the driving voltage line PL.

The driving thin-film transistor T1 may be electrically connected to the driving voltage line PL and the storage capacitor Cst, and may be configured to control a driving current flowing from the driving voltage line PL to the display element DPE, in response to a value (e.g., a level) of the voltage stored in the storage capacitor Cst. The display element DPE may emit light having a desired luminance (e.g., a predetermined or certain luminance) according to the driving current. An opposite electrode of the display element DPE may be supplied with a common voltage ELVSS.

Although FIG. 4 shows that the pixel circuit PC includes two thin-film transistors and one storage capacitor, the pixel circuit PC may include three or more thin-film transistors.

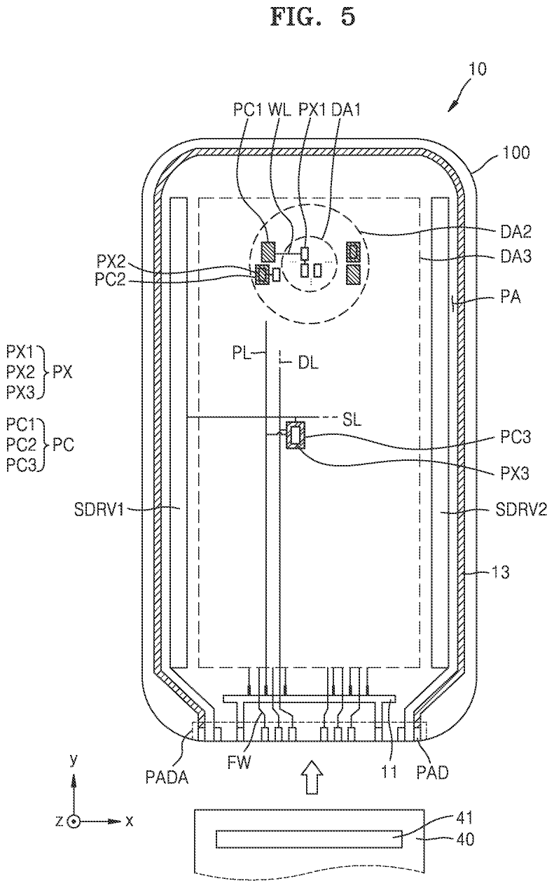

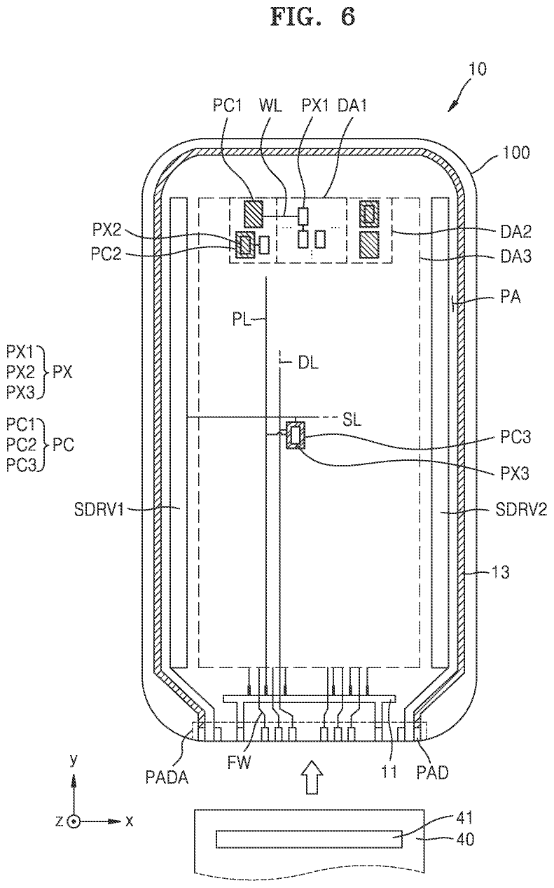

FIGS. 5 and 6 are schematic plan views of the display panel 10 of the display apparatus 1 according to one or more embodiments. In FIGS. 5 and 6, the same reference numerals are used to denote the same or substantially the same members as those described above with reference to FIGS. 1 and 2, and thus, redundant description thereof may not be repeated.

Referring to FIGS. 5 and 6, various components constituting the display panel 10 may be disposed on the substrate 100. In an embodiment, the substrate 100 may include the auxiliary display area DA1, the intermediate display area DA2, the main display area DA3, and the peripheral area PA. As shown in FIG. 5, the intermediate display area DA2 may entirely surround (e.g., around a periphery of) the auxiliary display area DA1. As another example, as shown in FIG. 6, the intermediate display area DA2 may be arranged on one or more sides of the auxiliary display area DA1. The main display area DA3 may at least partially surround (e.g., around a periphery of) the auxiliary display area DA1 and/or the intermediate display area DA2. The peripheral area PA may at least partially surround (e.g., around a periphery of) the main display area DA3.

A plurality of pixel circuits PC may be provided. The plurality of pixel circuits PC may include the auxiliary pixel circuit PC1, the intermediate pixel circuit PC2, and the main pixel circuit PC3. As described above, the auxiliary pixel circuit PC1 and the intermediate pixel circuit PC2 may be arranged at (e.g., in or on) the intermediate display area DA2. The main pixel circuit PC3 may be arranged at (e.g., in or on) the main display area DA3. The pixel circuit PC may not be arranged at (e.g., in or on) the auxiliary display area DA1. In other words, no pixel circuits PC may be arranged at (e.g., in or on) the auxiliary display area DA1.

The pixel PX may be implemented by a display element, such as an organic light-emitting diode. A plurality of pixels PX may be provided. The plurality of pixels PX may include the auxiliary pixel PX1, the intermediate pixel PX2, and the main pixel PX3. The auxiliary pixel PX1 may be arranged at (e.g., in or on) the auxiliary display area DA1. The auxiliary pixel PX1 may be implemented by a display element that is electrically connected to the auxiliary pixel circuit PC1 through the wiring WL. In an embodiment, one of a plurality of display elements arranged at (e.g., in or on) the auxiliary display area DA1 may be electrically connected to another one of the plurality of display elements arranged at (e.g., in or on) the auxiliary display area DA1. In this case, the one of the plurality of auxiliary pixels PX1 and the other one of the plurality of auxiliary pixels PX1 may equally or substantially equally emit light with each other by using one auxiliary pixel circuit PC1.

The intermediate pixel PX2 may be arranged at (e.g., in or on) the intermediate display area DA2. A display element arranged at (e.g., in or on) the intermediate display area DA2 may be electrically connected to the intermediate pixel circuit PC2. The display element arranged at (e.g., in or on) the intermediate display area DA2 may overlap with the intermediate pixel circuit PC2. In other words, the intermediate pixel PX2 may overlap with the intermediate pixel circuit PC2. In an embodiment, one of a plurality of display elements arranged at (e.g., in or on) the intermediate display area DA2 may be electrically connected to another one of the plurality of display elements arranged at (e.g., in or on) the intermediate display area DA2. In this case, the one of a plurality of intermediate pixels PX2 and the other one of the plurality of intermediate pixels PX2 may equally or substantially equally emit light with each other by using one intermediate pixel circuit PC2.

The main pixel PX3 may be arranged at (e.g., in or on) the main display area DA3. A display element arranged at (e.g., in or on) the main display area DA3 may be electrically connected to the main pixel circuit PC3. The display element arranged at (e.g., in or on) the main display area DA3 may overlap with the main pixel circuit PC3. In other words, the main pixel PX3 may overlap with the main pixel circuit PC3.

In an embodiment, the resolution of the display panel 10 in the auxiliary display area DA1 and/or the intermediate display area DA2 may be less than or equal to the resolution of the display panel 10 in the main display area DA3. For example, the resolution of the display panel 10 in the auxiliary display area DA1 and/or the intermediate display area DA2 may be about ½, about ⅜, about ⅓, about ¼, about 2/9, about ⅛, about 1/9, or about 1/16 of the resolution of the display panel 10 in the main display area DA3.

The pixels PX may not be arranged at (e.g., in or on) the peripheral area PA. A first scan driving circuit SDRV1, a second scan driving circuit SDRV2, a pad PAD, a driving voltage supply line 11, and a common voltage supply line 13 may be arranged at (e.g., in or on) the peripheral area PA.

One of the first scan driving circuit SDRV1 and the second scan driving circuit SDRV2 may apply a scan signal to the pixel circuit PC through the scan line SL. In an embodiment, the first scan driving circuit SDRV1 and the second scan driving circuit SDRV2 may be opposite to each other, with the main display area DA3 therebetween. In an embodiment, one of the plurality of pixels PX may receive a scan signal from the first scan driving circuit SDRV1, and another one of the plurality of pixels PX may receive a scan signal from the second scan driving circuit SDRV2.

The pad PAD may be arranged at (e.g., in or on) a pad area PADA at one side of the peripheral area PA. The pad PAD may be exposed without being covered by an insulating layer, and may be connected to a display circuit board 40. A display driver 41 may be disposed on the display circuit board 40.

The display driver 41 may generate a signal that is transmitted to the first scan driving circuit SDRV1 and the second scan driving circuit SDRV2. The display driver 41 may generate a data signal, and the generated data signal may be transmitted to the pixel circuit PC through a fan-out wiring FW, and the data line DL connected to the fan-out wiring FW.

The display driver 41 may supply the driving voltage ELVDD to the driving voltage supply line 11, and may supply the common voltage ELVSS to the common voltage supply line 13. The driving voltage ELVDD may be supplied to the pixel circuit PC through the driving voltage line PL connected to the driving voltage supply line 11, and the common voltage ELVSS may be supplied to an opposite electrode of a display element connected to the common voltage supply line 13.

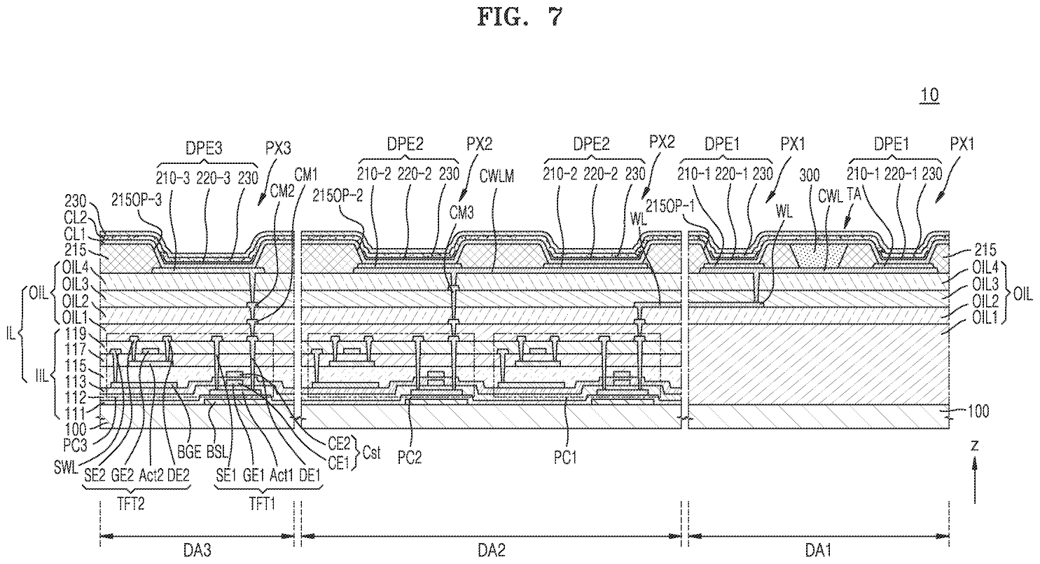

FIG. 7 is a schematic cross-sectional view of a portion of the display panel 10 of the display apparatus 1 according to an embodiment. Referring to FIG. 7, the display panel 10 may include the substrate 100, the insulating layer IL, the pixel circuit PC, the display element DPE, and a pixel-defining layer 215. In FIG. 7, the encapsulation layer ENL, the touch sensor layer TSL, and the optical functional layer OFL are omitted for convenience of illustration.

The substrate 100 may include glass, or a polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate. In an embodiment, the substrate 100 may have a multi-layered structure including a base layer including one or more of the above-described polymer resin, and a barrier layer. The substrate 100 including the polymer resin may be flexible, rollable, or bendable.

The insulating layer IL may be disposed on the substrate 100. The insulating layer IL may include an inorganic insulating layer IIL and an organic insulating layer OIL. In an embodiment, the inorganic insulating layer IIL may include a buffer layer 111, a first gate insulating layer 112, a second gate insulating layer 113, a first interlayer insulating layer 115, a third gate insulating layer 117, and a second interlayer insulating layer 119. In an embodiment, the inorganic insulating layer IIL may be arranged at (e.g., in or on) the intermediate display area DA2 and the main display area DA3 of the substrate 100, but may not be arranged at (e.g., in or on) the auxiliary display area DA1 of the substrate 100.

A plurality of pixel circuits PC may be provided. The plurality of pixel circuits PC may include the auxiliary pixel circuit PC1, the intermediate pixel circuit PC2, and the main pixel circuit PC3. In more detail, the auxiliary pixel circuit PC1 and the intermediate pixel circuit PC2 may be arranged at (e.g., in or on) the intermediate display area DA2, and the main pixel circuit PC3 may be arranged at (e.g., in or on) the main display area DA3. Because the auxiliary pixel circuit PC1, the intermediate pixel circuit PC2, and the main pixel circuit PC3 have the same or substantially the same structure as each other, the main pixel circuit PC3 is mainly described in more detail. The main pixel circuit PC3 may include a first thin-film transistor TFT1, a second thin-film transistor TFT2, and the storage capacitor Cst. The first thin-film transistor TFT1 may include a first semiconductor layer Act1, a first gate electrode GE1, a first source electrode SE1, and a first drain electrode DE1. The second thin-film transistor TFT2 may include a second semiconductor layer Act2, a second gate electrode GE2, a second source electrode SE2, and a second drain electrode DE2. The storage capacitor Cst may include a lower electrode CE1 and an upper electrode CE2.

The buffer layer 111 may be disposed on the substrate 100. The buffer layer 111 may include an inorganic insulating material, such as SiN_{X}, SiO_{X}N_{Y}, and/or SiO_{X}, and may have a single-layer structure or a multi-layered structure including one or more of the above-described inorganic insulating materials.

The first semiconductor layer Act1 may include a silicon semiconductor. The first semiconductor layer Act1 may include polysilicon. As another example, the first semiconductor layer Act1 may include amorphous silicon. As another example, the first semiconductor layer Act1 may include an oxide semiconductor or an organic semiconductor. The first semiconductor layer Act1 may include a channel area, and a drain area and a source area that are respectively arranged on opposite sides of the channel area.

The first gate electrode GE1 may overlap with the first semiconductor layer Act1. In more detail, the first gate electrode GE1 may overlap with the channel area of the first semiconductor layer Act1. The first gate electrode GE1 may include a low-resistance metal material. The first gate electrode GE1 may include a conductive material including molybdenum (Mo), aluminum (Al), copper (Cu), titanium (Ti), and/or the like, and may have a single-layer structure or a multi-layered structure including one or more of the above-described materials.

The first gate insulating layer 112 may be arranged between the first semiconductor layer Act1 and the first gate electrode GE1. Accordingly, the first semiconductor layer Act1 may be insulated from the first gate electrode GE1. The first gate insulating layer 112 may include an inorganic insulating material, such as SiO_{X}, SiN_{X}, SiO_{X}N_{Y}, Al₂O₃, TiO₂, Ta₂O₅, hafnium oxide (HfO₂), and/or ZnO.

The second gate insulating layer 113 may cover the first gate electrode GE1. The second gate insulating layer 113 may be disposed on the first gate electrode GE1. The second gate insulating layer 113 may include an inorganic insulating material, such as SiO_{X}, SiN_{X}, SiO_{X}N_{Y}, Al₂O₃, TiO₂, Ta₂O₅, HfO₂, and/or ZnO.

The upper electrode CE2 may be disposed on the second gate insulating layer 113. The upper electrode CE2 may overlap with the first gate electrode GE1 thereunder. In this case, the upper electrode CE2 may overlap with the first gate electrode GE1, with the second gate insulating layer 113 therebetween, to constitute the storage capacitor Cst. In other words, the first gate electrode GE1 of the first thin-film transistor TFT1 may serve as the lower electrode CE1 of the storage capacitor Cst. As described above, the storage capacitor Cst and the first thin-film transistor TFT1 may be formed to overlap with each other. However, the present disclosure is not limited thereto. For example, the storage capacitor Cst may be formed to not overlap with the first thin-film transistor TFT1.

The upper electrode CE2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu, and may have a single-layer structure or a multi-layered structure including one or more of the above-described materials.

The first interlayer insulating layer 115 may cover the upper electrode CE2. The first interlayer insulating layer 115 may include SiO_{X}, SiN_{X}, SiO_{X}N_{Y}, Al₂O₃, TiO₂, Ta₂O₅, HfO₂, or ZnO. The first interlayer insulating layer 115 may have a single-layer structure or a multi-layered structure including one or more of the above-described inorganic insulating materials.

The second semiconductor layer Act2 may be disposed on the first interlayer insulating layer 115. The second semiconductor layer Act2 may include an oxide semiconductor. For example, the second semiconductor layer Act2 may include a zinc (Zn) oxide-based material, such as Zn oxide, indium (In)—Zn oxide, or gallium (Ga)—In—Zn oxide. As another example, the second semiconductor layer Act2 may include an In—Ga—Zn—O (IGZO), In—Sn—Zn—O (ITZO), or In—Ga—Sn—Zn—O (IGTZO) semiconductor containing a metal, such as In, Ga, or tin (Sn), in ZnO.

In an embodiment, the second semiconductor layer Act2 may include a channel area, and a source area and a drain area that are respectively arranged on opposite sides of the channel area. The source area and the drain area of the second semiconductor layer Act2 may be formed by adjusting a carrier concentration of an oxide semiconductor to make the oxide semiconductor conductive. For example, the source area and the drain area of the second semiconductor layer Act2 may be formed by increasing the carrier concentration by performing a plasma treatment using a hydrogen-based gas, a fluorine-based gas, or a suitable combination thereof on the oxide semiconductor.

The third gate insulating layer 117 may cover the second semiconductor layer Act2. The third gate insulating layer 117 may be arranged between the second semiconductor layer Act2 and the second gate electrode GE2. In an embodiment, the third gate insulating layer 117 may be disposed over the entire or substantially the entire substrate 100. In another embodiment, the third gate insulating layer 117 may be patterned according to a shape of the second gate electrode GE2. The third gate insulating layer 117 may include SiO_{X}, SiN_{X}, SiO_{X}N_{Y}, Al₂O₃, TiO₂, Ta₂O₅, HfO₂, or ZnO. The third gate insulating layer 117 may have a single-layer structure or a multi-layered structure including one or more of the above-described inorganic insulating materials.

The second gate electrode GE2 may be disposed on the third gate insulating layer 117. The second gate electrode GE2 may overlap with the second semiconductor layer Act2. In more detail, the second gate electrode GE2 may overlap with the channel area of the second semiconductor layer Act2. The second gate electrode GE2 may include a conductive material including Mo, Al, Cu, Ti, and/or the like, and may have a single-layer structure or a multi-layered structure including one or more of the above-described materials.

The second interlayer insulating layer 119 may cover the second gate electrode GE2. The second interlayer insulating layer 119 may include SiO_{X}, SiN_{X}, SiO_{X}N_{Y}, Al₂O₃, TiO₂, Ta₂O₅, HfO₂, or ZnO. The second interlayer insulating layer 119 may have a single-layer structure or a multi-layered structure including one or more of the above-described inorganic insulating materials.

The first source electrode SE1 and the first drain electrode DE1 may be disposed on the second interlayer insulating layer 119. The first source electrode SE1 and the first drain electrode DE1 may be electrically connected to the first semiconductor layer Act1. The first source electrode SE1 and the first drain electrode DE1 may be electrically connected to the first semiconductor layer Act1 through contact holes formed in (e.g., penetrating) some of the insulating layers.

The second source electrode SE2 and the second drain electrode DE2 may be disposed on the second interlayer insulating layer 119. The second source electrode SE2 and the second drain electrode DE2 may be electrically connected to the second semiconductor layer Act2. The second source electrode SE2 and the second drain electrode DE2 may be electrically connected to the second semiconductor layer Act2 through contact holes formed in (e.g., penetrating) some of the insulating layers.

Each of the first source electrode SE1, the first drain electrode DE1, the second source electrode SE2, and the second drain electrode DE2 may include a suitable material having high conductivity. Each of the first source electrode SE1, the first drain electrode DE1, the second source electrode SE2, and the second drain electrode DE2 may include a conductive material including, for example, Mo, Al, Cu, Ti, and/or the like, and may have a single-layer structure or a multi-layered structure including one or more of the above-described materials. In an embodiment, each of the first source electrode SE1, the first drain electrode DE1, the second source electrode SE2, and the second drain electrode DE2 may have a multi-layered structure of Ti/Al/Ti.

Because the first thin-film transistor TFT1 having the first semiconductor layer Act1 including a silicon semiconductor has high reliability, the first thin-film transistor TFT1 may be employed as a driving thin-film transistor to implement a high-quality display panel 10.

Because an oxide semiconductor has high carrier mobility and low leakage current, a voltage drop may not be large even when a driving time is long. In other words, because a color change of an image due to a voltage drop is not large even in low frequency driving, low frequency driving may be possible. As described above, because an oxide semiconductor has low leakage current, the oxide semiconductor may be employed in at least one of the thin-film transistors other than the driving thin-film transistor, to prevent or substantially prevent the leakage current and reduce power consumption. For example, the second thin-film transistor TFT2 may be employed as a switching thin-film transistor. As another example, when the main pixel circuit PC3 includes a plurality of thin-film transistors, some of the thin-film transistors of the plurality of thin-film transistors may employ a silicon semiconductor, and other (e.g., the remaining) thin-film transistors may employ an oxide semiconductor.

A lower gate electrode BGE may be disposed under the second semiconductor layer Act2. In an embodiment, the lower gate electrode BGE may be arranged between the second gate insulating layer 113 and the first interlayer insulating layer 115. In an embodiment, the lower gate electrode BGE may receive a gate signal. In this case, the second thin-film transistor TFT2 may have a double gate electrode structure in which gate electrodes thereof are disposed above and below the second semiconductor layer Act2.

In an embodiment, a sub-wiring SWL may be arranged between the third gate insulating layer 117 and the second interlayer insulating layer 119. In an embodiment, the sub-wiring SWL may be electrically connected to the lower gate electrode BGE through contact holes formed in (e.g., penetrating) the first interlayer insulating layer 115 and the third gate insulating layer 117.

In an embodiment, a lower blocking layer BSL may be arranged between the substrate 100 and the main pixel circuit PC3. In an embodiment, the lower blocking layer BSL may overlap with the first thin-film transistor TFT1. A constant or substantially constant voltage may be applied to the lower blocking layer BSL. Because the lower blocking layer BSL is disposed under the first thin-film transistor TFT1, the first thin-film transistor TFT1 may be less affected by surrounding interference signals, and thus, reliability of the first thin-film transistor TFT1 may be improved.

The lower blocking layer BSL may include a transparent conductive material. For example, the lower blocking layer BSL may include a transparent conducting oxide (TCO). The lower blocking layer BSL may include a suitable conductive oxide, such as indium tin oxide (ITO), indium zinc oxide (IZO), ZnO, indium oxide (In₂O₃), indium gallium oxide (IGO), or aluminum zinc oxide (AZO).

Still referring to FIG. 7, the organic insulating layer OIL may be disposed on the inorganic insulating layer IIL. The organic insulating layer OIL may include a first organic insulating layer OIL1, a second organic insulating layer OIL2, a third organic insulating layer OIL3, and a fourth organic insulating layer OIL4. However, the present disclosure is not limited thereto. The organic insulating layer OIL may include the first organic insulating layer OIL1 and the second organic insulating layer OIL2, or may include the first organic insulating layer OIL1, the second organic insulating layer OIL2, and the third organic insulating layer OIL3. In other words, the organic insulating layer OIL may include two or three layers, instead of the four layers.

The first organic insulating layer OIL1 may cover the first source electrode SE1, the first drain electrode DE1, the second source electrode SE2, and the second drain electrode DE2. The first organic insulating layer OIL1 may include an organic material. For example, the first organic insulating layer OIL1 may include an organic insulating material including a general-purpose polymer, such as polymethylmethacrylate (PMMA) or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and/or a suitable blend thereof.

A first connection electrode CM1 may be disposed on the first organic insulating layer OIL1. The first connection electrode CM1 may be electrically connected to the first source electrode SE1 or the first drain electrode DE1 of the pixel circuit PC through a contact hole formed in (e.g., penetrating) the first organic insulating layer OIL1. The first connection electrode CM1 may include a suitable material having high conductivity. The first connection electrode CM1 may include a conductive material including Mo, Al, Cu, Ti, and/or the like, and may have a single-layer structure or a multi-layered structure including one or more of the above-described materials. In an embodiment, the first connection electrode CM1 may have a multi-layered structure of Ti/Al/Ti.

The second organic insulating layer OIL2 may cover the first connection electrode CM1. The second organic insulating layer OIL2 may include an organic material. In an embodiment, the second organic insulating layer OIL2 may include the same or substantially the same material as that of the first organic insulating layer OIL1. In another embodiment, the second organic insulating layer OIL2 may include a material different from that of the first organic insulating layer OIL1.

A second connection electrode CM2 may be disposed on the second organic insulating layer OIL2. In this regard, the second connection electrode CM2 may be electrically connected to the first connection electrode CM1 through a contact hole formed in (e.g., penetrating) the second organic insulating layer OIL2. The second connection electrode CM2 may include a suitable material having high conductivity. The second connection electrode CM2 may include a conductive material including Mo, Al, Cu, Ti, and/or the like, and may have a single-layer structure or a multi-layered structure including one or more of the above-described materials. In an embodiment, the second connection electrode CM2 may have a multi-layered structure of Ti/Al/Ti.

The third organic insulating layer OIL3 may cover the second connection electrode CM2. The third organic insulating layer OIL3 may include an organic material. In an embodiment, the third organic insulating layer OIL3 may include the same or substantially the same material as that of the first organic insulating layer OIL1. In another embodiment, the third organic insulating layer OIL3 may include a material different from that of the first organic insulating layer OIL1.

A third connection electrode CM3 may be disposed on the third organic insulating layer OIL3. In this regard, the third connection electrode CM3 may be electrically connected to the first connection electrode CM1 through contact holes formed in (e.g., penetrating) the second organic insulating layer OIL2 and the third organic insulating layer OIL3. The third connection electrode CM3 may include a suitable material having high conductivity. The third connection electrode CM3 may include a conductive material including Mo, Al, Cu, Ti, and/or the like, and may have a single-layer structure or a multi-layered structure including one or more of the above-described materials. In an embodiment, the third connection electrode CM3 may have a multi-layered structure of Ti/Al/Ti.

The fourth organic insulating layer OIL4 may cover the third connection electrode CM3. The fourth organic insulating layer OIL4 may include an organic material. In an embodiment, the fourth organic insulating layer OIL4 may include the same or substantially the same material as that of the first organic insulating layer OIL1. In another embodiment, the fourth organic insulating layer OIL4 may include a material different from that of the first organic insulating layer OIL1.

The display element DPE may be disposed on the organic insulating layer OIL. A plurality of display elements DPE may be provided. The plurality of display elements DPE may include the auxiliary display element DPE1, the intermediate display element DPE2, and the main display element DPE3. The auxiliary display element DPE1 may include an auxiliary pixel electrode 210-1, an auxiliary emission layer 220-1, and an opposite electrode 230. The intermediate display element DPE2 may include an intermediate pixel electrode 210-2, an intermediate emission layer 220-2, and the opposite electrode 230. The main display element DPE3 may include a main pixel electrode 210-3, a main emission layer 220-3, and the opposite electrode 230.

In more detail, the auxiliary pixel electrode 210-1, the intermediate pixel electrode 210-2, and the main pixel electrode 210-3 may be disposed on the organic insulating layer OIL. For example, the auxiliary pixel electrode 210-1, the intermediate pixel electrode 210-2, and the main pixel electrode 210-3 may be disposed on the fourth organic insulating layer OIL4. The auxiliary pixel electrode 210-1 may be arranged at (e.g., in or on) the auxiliary display area DA1, the intermediate pixel electrode 210-2 may be arranged at (e.g., in or on) the intermediate display area DA2, and the main pixel electrode 210-3 may be arranged at (e.g., in or on) the main display area DA3.

Each of the auxiliary pixel electrode 210-1, the intermediate pixel electrode 210-2, and the main pixel electrode 210-3 may include a conductive oxide, such as ITO, IZO, ZnO, In₂O₃, IGO, or AZO. As another example, each of the auxiliary pixel electrode 210-1, the intermediate pixel electrode 210-2, and the main pixel electrode 210-3 may include a reflective film including Ag, Mg, Al, Pt, Pd, Au, Ni, Nd, Ir, Cr, or a suitable compound thereof. As another example, each of the auxiliary pixel electrode 210-1, the intermediate pixel electrode 210-2, and the main pixel electrode 210-3 may further include a suitable film including ITO, IZO, ZnO, or In₂O₃ above or below the reflective film.

The display element DPE may be electrically connected to the pixel circuit PC. When the display element DPE is described as being electrically connected to the pixel circuit PC, it may be understood that a pixel electrode included in the display element DPE is electrically connected to a source electrode or a drain electrode of the pixel circuit PC.

For example, the main pixel electrode 210-3 of the main display element DPE3 may be electrically connected to the second connection electrode CM2 through contact holes formed in (e.g., penetrating) the third organic insulating layer OIL3 and the fourth organic insulating layer OIL4. The second connection electrode CM2 may be electrically connected to the main pixel circuit PC3 through the first connection electrode CM1.

For example, the intermediate pixel electrode 210-2 of the intermediate display element DPE2 may be electrically connected to an intermediate connection wiring CWLM, and the intermediate connection wiring CWLM may be electrically connected to the third connection electrode CM3 through a contact hole formed in (e.g., penetrating) the fourth organic insulating layer OIL4. The third connection electrode CM3 may be electrically connected to the intermediate pixel circuit PC2 through the first connection electrode CM1.

For example, the auxiliary pixel electrode 210-1 of the auxiliary display element DPE1 may be electrically connected to an auxiliary connection wiring CWL, and the auxiliary connection wiring CWL may be electrically connected to the wiring WL through contact holes formed in (e.g., penetrating) the third organic insulating layer OIL3 and the fourth organic insulating layer OIL4. The wiring WL may extend from the auxiliary display area DA1 to the intermediate display area DA2. Accordingly, the wiring WL may be electrically connected to the first connection electrode CM1 through a contact hole formed in (e.g., penetrating) the second organic insulating layer OIL2 at (e.g., in or on) the intermediate display area DA2. The wiring WL may be electrically connected to the auxiliary pixel circuit PC1 through the first connection electrode CM1. The wiring WL may include a transparent conductive material.

Accordingly, at (e.g., in or on) the main display area DA3, the main display element DPE3 may be electrically connected to the main pixel circuit PC3 to implement the main pixel PX3. In an embodiment, the main display element DPE3 may overlap with the main pixel circuit PC3. At (e.g., in or on) the auxiliary display area DA1, the auxiliary display element DPE1 may be electrically connected to the auxiliary pixel circuit PC1 to implement the auxiliary pixel PX1. Further, at (e.g., in or on) the intermediate display area DA2, the intermediate display element DPE2 may be electrically connected to the intermediate pixel circuit PC2 to implement the intermediate pixel PX2. In an embodiment, the auxiliary pixel circuit PC1 and the intermediate pixel circuit PC2 may be arranged at (e.g., in or on) the intermediate display area DA2.

Each of the intermediate connection wiring CWLM and the auxiliary connection wiring CWL may include a transparent conductive material. For example, each of the intermediate connection wiring CWLM and the auxiliary connection wiring CWL may include a TCO. Each of the intermediate connection wiring CWLM and the auxiliary connection wiring CWL may include a conductive oxide, such as ITO, IZO, ZnO, In₂O₃, IGO, or AZO.

The wiring WL may include a TCO. The wiring WL may include a conductive oxide, such as ITO, IZO, ZnO, In₂O₃, IGO, or AZO.

The pixel-defining layer 215 may be disposed on the organic insulating layer OIL. The pixel defining layer 215 may define each pixel PX by having an opening corresponding to each pixel PX. In more detail, a main opening 2150P-3 defined in (e.g., penetrating) the pixel-defining layer 215 may expose a central portion of the main pixel electrode 210-3, and an emission area of light emitted from the main display element DPE3 may be defined by the main opening 2150P-3. Similarly, an auxiliary opening 2150P-1 defined in (e.g., penetrating) the pixel-defining layer 215 may expose a central portion of the auxiliary pixel electrode 210-1, and an emission area of light emitted from the auxiliary display element DPE1 may be defined by the auxiliary opening 2150P-1. Similarly, an intermediate opening 2150P-2 defined in (e.g., penetrating) the pixel-defining layer 215 may expose a central portion of the intermediate pixel electrode 210-2, and an emission area of light emitted from the intermediate display element DPE2 may be defined by the intermediate opening 2150P-2.

As shown in FIG. 7, the pixel-defining layer 215 may prevent an arc and/or the like from occurring at an edge of each of the auxiliary pixel electrode 210-1, the intermediate pixel electrode 210-2, and the main pixel electrode 210-3 by increasing a distance between the edge of each of the auxiliary pixel electrode 210-1, the intermediate pixel electrode 210-2, and the main pixel electrode 210-3 and the opposite electrode 230 above the auxiliary pixel electrode 210-1, the intermediate pixel electrode 210-2, and the main pixel electrode 210-3. The pixel-defining layer 215 may include an organic material, such as polyimide or hexamethyldisiloxane (HMDSO).

The pixel-defining layer 215 may include a light-blocking material. The light-blocking material may include at least one of a black pigment, a black dye, or black particles. For example, the light-blocking material may include at least one of Cr, chrome oxide (CrOₓ), or chrome nitride (CrNₓ), or may include a resin, graphite, a non-Cr-based pigment, a lactam-based pigment, or a perylene-based pigment. The black pigment may include at least one of aniline black, lactam black, or perylene black. In the case of the display apparatus 1 according to the present embodiment, because the pixel-defining layer 215 includes the light-blocking material, light may be blocked from passing through the display panel 10 by the light-blocking material, or even when light passes through the display panel 10, the degree of transmission of the light may be reduced by the light-blocking material.

In a portion of the auxiliary display area DA1, the pixel-defining layer 215 may not be disposed on the organic insulating layer OIL, and an organic layer 300 may be disposed on the organic insulating layer OIL. The organic layer 300 may include a transparent organic insulating material. For example, the organic layer 300 may include a polymer-based material. The polymer-based material may be transparent. For example, the organic layer 300 may include at least one of a silicone-based resin, an acrylic resin, an epoxy-based resin, polyimide, HMDSO, or polyethylene. Unlike the pixel-defining layer 215, the organic layer 300 may not include the light-blocking material. Accordingly, light passing through the display panel 10 through a transmission area TA may not be blocked by the light-blocking material.

As described above, in some regions of the auxiliary display area DA1, the organic layer 300 that includes a transparent organic insulating material and does not include a light-blocking material may be disposed on the organic insulating layer OIL. Accordingly, such regions may have a higher light transmittance than that of other regions of the auxiliary display area DA1. In other words, the light transmittance of the display panel 10 may be improved.

The main emission layer 220-3 may be disposed on the main pixel electrode 210-3. The auxiliary emission layer 220-1 may be disposed on the auxiliary pixel electrode 210-1. The intermediate emission layer 220-2 may be disposed on the intermediate pixel electrode 210-2. Each of the auxiliary emission layer 220-1, the intermediate emission layer 220-2, and the main emission layer 220-3 may include a low-molecular weight material or a high-molecular weight material, and may emit green light, red light, blue light, or white light.

The opposite electrode 230 may be disposed on the auxiliary emission layer 220-1, the intermediate emission layer 220-2, and the main emission layer 220-3. In other words, the opposite electrode 230 may be integrally formed over the plurality of display elements DPE to correspond to a plurality of pixel electrodes, for example, such as the auxiliary pixel electrode 210-1, the intermediate pixel electrode 210-2, and the main pixel electrode 210-3. Because the opposite electrode 230 is formed to cover the entire or substantially the entire display area, the opposite electrode 230 may also be disposed on the pixel-defining layer 215 and the organic layer 300. The opposite electrode 230 may include a conductive material having a low work function. For example, the opposite electrode 230 may include a (semi-) transparent layer including Ag, Mg, Al, Pt, Pd, Au, Ni, Nd, Ir, Cr, lithium (Li), Ca, or a suitable alloy thereof. As another example, the opposite electrode 230 may further include a layer including ITO, IZO, ZnO, or In₂O₃ on the (semi-) transparent layer including one or more of the above-described materials.

The auxiliary display element DPE1, the intermediate display element DPE2, and the main display element DPE3 may further include a first common layer CL1 and a second common layer CL2. The first common layer CL1 may be arranged between the auxiliary pixel electrode 210-1 and the auxiliary emission layer 220-1, between the intermediate pixel electrode 210-2 and the intermediate emission layer 220-2, and between the main pixel electrode 210-3 and the main emission layer 220-3. The second common layer CL2 may be arranged between the opposite electrode 230 and the auxiliary emission layer 220-1, between the opposite electrode 230 and the intermediate emission layer 220-2, and between the opposite electrode 230 and the main emission layer 220-3.

Like the opposite electrode 230, the first common layer CL1 and the second common layer CL2 may be common layers that are arranged over the entire or substantially the entire display area. In other words, the first common layer CL1 and the second common layer CL2 may be formed to cover the entire or substantially the entire display area. In other words, like the opposite electrode 230, the first common layer CL1 and the second common layer CL2 may be integrally formed over the plurality of display elements DPE to correspond to a plurality of pixel electrodes, for example, such as the auxiliary pixel electrode 210-1, the intermediate pixel electrode 210-2, and the main pixel electrode 210-3.

The first common layer CL1 may include, for example, a hole transport layer (HTL), or may include an HTL and a hole injection layer (HIL). The first common layer CL1 may have a single-layer structure or a multi-layered structure. For example, when the first common layer CL1 includes a high-molecular weight material, the first common layer CL1 may be an HTL having a single-layer structure, and may include poly-(3,4-ethylenedioxythiophene) (PEDOT), polyaniline (PANI), N, N′-diphenyl-N,N′-bis(3-methylphenyl)-1,1′-bi-phenyl-4,4′-diamine (TPD), or N,N′-di(naphthalen-1-yl)-N,N′-diphenyl-benzidine (NPB). When the first common layer CL1 includes a low-molecular weight material, the first common layer CL1 may include an HIL and an HTL.

The second common layer CL2 may include an electron transport layer (ETL) and/or an electron injection layer (EIL). The second common layer CL2 may have a single-layer structure or a multi-layered structure. The opposite electrode 230 may be disposed on the second common layer CL2. In some embodiments, the second common layer CL2 may be omitted as needed or desired. In other words, the second common layer CL2 may not be provided. For example, when the first common layer CL1, the auxiliary emission layer 220-1, the intermediate emission layer 220-2, and the main emission layer 220-3 include a high-molecular weight material, it may be desirable to further form the second common layer CL2. However, hereinafter, a case in which the display panel 10 includes the first common layer CL1 and the second common layer CL2 is mainly described in more detail for convenience.

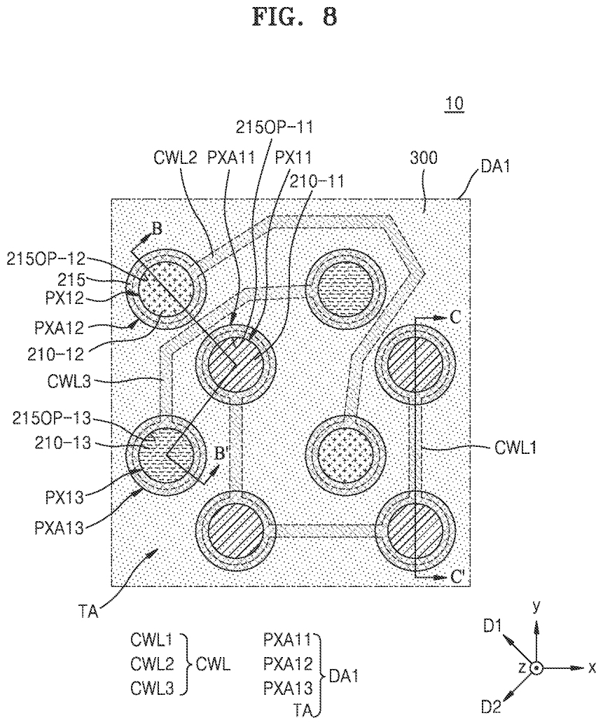

FIG. 8 is a schematic plan view of a portion of the display panel 10 of the display apparatus 1 according to an embodiment. In more detail, FIG. 8 is a schematic plan view of a portion of the auxiliary display area DA1 of the display panel 10 of the display apparatus 1 according to an embodiment. In FIG. 8, a plan view of the pixel-defining layer 215 and the organic layer 300 is shown for convenience of illustration. Further, for convenience of illustration, the auxiliary connection wiring CWL is also shown.

Referring to FIG. 8, the auxiliary display area DA1 of the substrate 100 may include a plurality of auxiliary pixel areas, in which a plurality of auxiliary pixels PX1 are arranged. For example, the auxiliary display area DA1 may include a first auxiliary pixel area PXA11, a second auxiliary pixel area PXA12, and a third auxiliary pixel area PXA13. A plurality of first auxiliary pixel areas PXA11 may be provided, a plurality of second auxiliary pixel areas PXA12 may be provided, and a plurality of third auxiliary pixel areas PXA13 may be provided. The second auxiliary pixel area PXA12 may be arranged adjacent to the first auxiliary pixel area PXA11 in a first direction D1 (e.g., a direction between a −x direction and a +y direction). The third auxiliary pixel area PXA13 may be arranged adjacent to the first auxiliary pixel area PXA11 in a second direction D2 (e.g., a direction between the −x direction and a −y direction) crossing the first direction D1.

The auxiliary display area DA1 may further include the transmission area TA. The transmission area TA may be arranged between the plurality of auxiliary pixel areas. In more detail, the transmission area TA may be arranged between the first auxiliary pixel area PXA11 and the second auxiliary pixel area PXA12, between the first auxiliary pixel area PXA11 and the third auxiliary pixel area PXA13, and between the second auxiliary pixel area PXA12 and the third auxiliary pixel area PXA13. The transmission area TA may also be arranged between the first auxiliary pixel areas PXA11, between the second auxiliary pixel areas PXA12, and between the third auxiliary pixel areas PXA13. In other words, in more detail, when viewed (e.g., in a plan view) from a direction perpendicular to or substantially perpendicular to the substrate 100 (e.g., in a z-axis direction), the transmission area TA may surround (e.g., around a periphery of) each of the first auxiliary pixel area PXA11, the second auxiliary pixel area PXA12, and the third auxiliary pixel area PXA13. In other words, the transmission area TA may have a mesh shape. Accordingly, each of the first auxiliary pixel area PXA11, the second auxiliary pixel area PXA12, and the third auxiliary pixel area PXA13 may have an island shape.

Each of the auxiliary pixels PX1 may refer to a sub-pixel, and may include the auxiliary display element DPE1. The auxiliary pixel PX1 may emit, for example, green light, red light, or blue light. For example, the auxiliary pixel PX1 may be a first auxiliary pixel PX11 that emits green light, a second auxiliary pixel PX12 that emits red light, or a third auxiliary pixel PX13 that emits blue light. The green light may be light in a wavelength band of about 495 nm to about 580 nm. The red light may be light in a wavelength band of about 580 nm to about 780 nm. The blue light may be light in a wavelength band of about 400 nm to about 495 nm.

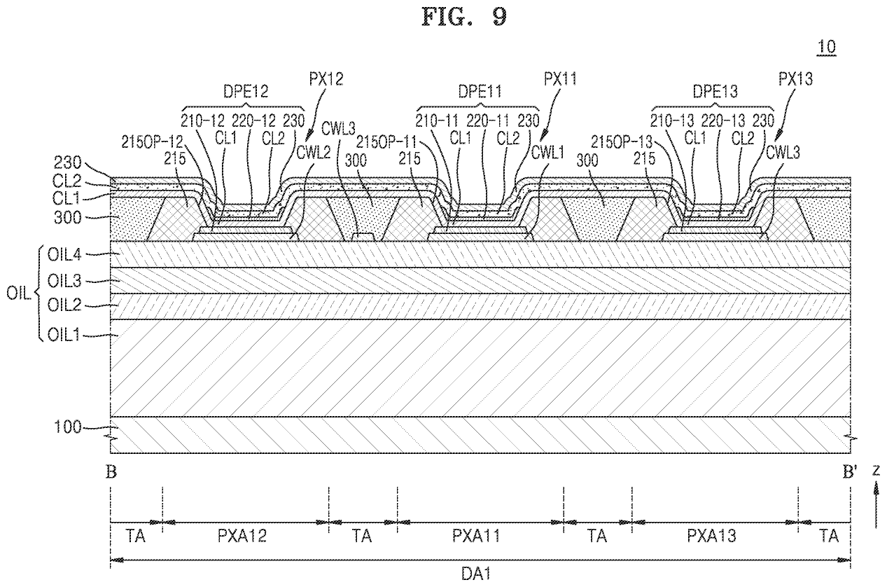

The first auxiliary pixel PX11 may be arranged at (e.g., in or on) the first auxiliary pixel area PXA11, the second auxiliary pixel PX12 may be arranged at (e.g., in or on) the second auxiliary pixel area PXA12, and the third auxiliary pixel PX13 may be arranged at (e.g., in or on) the third auxiliary pixel area PXA13. In more detail, a first auxiliary pixel electrode 210-11 of a first auxiliary display element DPE11 (e.g., see FIG. 9) may be arranged at (e.g., in or on) the first auxiliary pixel area PXA11 to implement the first auxiliary pixel PX11. A second auxiliary pixel electrode 210-12 of a second auxiliary display element DPE12 (e.g., see FIG. 9) may be arranged at (e.g., in or on) the second auxiliary pixel area PXA12 to implement the second auxiliary pixel PX12. A third auxiliary pixel electrode 210-13 of a third auxiliary display element DPE13 (e.g., see FIG. 9) may be arranged at (e.g., in or on) the third auxiliary pixel area PXA13 to implement the third auxiliary pixel PX13. For example, the first auxiliary pixel electrode 210-11, the second auxiliary pixel electrode 210-12, and the third auxiliary pixel electrode 210-13 may be arranged to be spaced apart from each other in a plan view. As shown in FIG. 8, the first auxiliary pixel electrode 210-11, the second auxiliary pixel electrode 210-12, and the third auxiliary pixel electrode 210-13 may have the same or substantially the same size or similar sizes as each other. As another example, in another embodiment, the first auxiliary pixel electrode 210-11, the second auxiliary pixel electrode 210-12, and the third auxiliary pixel electrode 210-13 may have different sizes from one another.

The auxiliary connection wiring CWL may be disposed under the auxiliary pixel electrodes 210-1. The auxiliary connection wiring CWL may include a first auxiliary connection wiring CWL1, a second auxiliary connection wiring CWL2, and a third auxiliary connection wiring CWL3. In more detail, the first auxiliary connection wiring CWL1 may be disposed under the first auxiliary pixel electrode 210-11, the second auxiliary connection wiring CWL2 may be disposed under the second auxiliary pixel electrode 210-12, and the third auxiliary connection wiring CWL3 may be disposed under the third auxiliary pixel electrode 210-13. In other words, the first auxiliary connection wiring CWL1 may be arranged at (e.g., in or on) the first auxiliary pixel area PXA11, the second auxiliary connection wiring CWL2 may be arranged at (e.g., in or on) the second auxiliary pixel area PXA12, and the third auxiliary connection wiring CWL3 may be arranged at (e.g., in or on) the third auxiliary pixel area PXA13.

In an embodiment, the auxiliary connection wiring CWL may electrically connect the auxiliary display elements DPE1 to one another. For example, a plurality of first auxiliary display elements DPE11 may be provided (e.g., see FIG. 9), and the first auxiliary connection wiring CWL1 may electrically connect the first auxiliary display elements DPE11 to each other. For example, four first auxiliary display elements DPE11 may be electrically connected to each other by the first auxiliary connection wiring CWL1. In other words, four first auxiliary pixel electrodes 210-11 may be electrically connected to each other by the first auxiliary connection wiring CWL1.

A plurality of second auxiliary display elements DPE12 (e.g., see FIG. 9) may be provided, and the second auxiliary connection wiring CWL2 may electrically connect the second auxiliary display elements DPE12 to each other. For example, two second auxiliary display elements DPE12 may be electrically connected to each other by the second auxiliary connection wiring CWL2. In other words, two second auxiliary pixel electrodes 210-12 may be electrically connected to each other by the second auxiliary connection wiring CWL2. A plurality of third auxiliary display elements DPE13 may be provided, and the third auxiliary connection wiring CWL3 may electrically connect the third auxiliary display elements DPE13 to each other. For example, two third auxiliary display elements DPE13 may be electrically connected to each other by the third auxiliary connection wiring CWL3. In other words, two third auxiliary pixel electrodes 210-13 may be electrically connected to each other by the third auxiliary connection wiring CWL3.

In more detail, because the first auxiliary display element DPE11 may be provided in a plurality, the first auxiliary pixel electrode 210-11 included in the first auxiliary display elements DPE11 may be provided in a plurality. The first auxiliary connection wiring CWL1 arranged in one first auxiliary pixel area PXA11 may be disposed under one first auxiliary pixel electrode 210-11. The first auxiliary connection wiring CWL1 may extend to the transmission area TA. The first auxiliary connection wiring CWL1 may extend from the transmission area TA to another first auxiliary pixel area PXA11. The first auxiliary connection wiring CWL1 extending to the other first auxiliary pixel area PXA11 may be disposed under another first auxiliary pixel electrode 210-11. In other words, the first auxiliary connection wiring CWL1 may extend from the one first auxiliary pixel area PXA11 to the transmission area TA, and the first auxiliary connection wiring CWL1 extending to the transmission area TA may extend from the transmission area TA to the other first auxiliary pixel area PXA11. In other words, the first auxiliary connection wiring CWL1 may extend from the one first auxiliary pixel area PXA11 to the other first auxiliary pixel area PXA11 through the transmission area TA. Accordingly, the first auxiliary connection wiring CWL1 may electrically connect the first auxiliary display elements DPE11 to each other. In other words, the first auxiliary connection wiring CWL1 may electrically connect the first auxiliary pixel electrodes 210-11 to each other.

A plurality of second auxiliary pixel electrodes 210-12 may be provided, and the above description of the first auxiliary pixel electrodes 210-11 and the first auxiliary connection wiring CWL1 may be similarly applied to the second auxiliary pixel electrodes 210-12 and the second auxiliary connection wiring CWL2. Further, a plurality of third auxiliary pixel electrodes 210-13 may be provided, and the above description of the first auxiliary pixel electrodes 210-11 and the first auxiliary connection wiring CWL1 may be similarly applied to the third auxiliary pixel electrodes 210-13 and the third auxiliary connection wiring CWL3. In other words, the second auxiliary connection wiring CWL2 may electrically connect the second auxiliary pixel electrodes 210-12 to each other, and the third auxiliary connection wiring CWL3 may electrically connect the third auxiliary pixel electrodes 210-13 to each other. Accordingly, redundant description thereof will not be repeated.

Although FIGS. 7 and 8 show that the auxiliary connection wiring CWL is disposed under the auxiliary pixel electrode 210-1, the present disclosure is not limited thereto. For example, the auxiliary connection wiring CWL may be arranged at (e.g., in or on) the same layer as that of the auxiliary pixel electrode 210-1, and may include the same material as that of the auxiliary pixel electrode 210-1. In other words, the auxiliary connection wiring CWL and the auxiliary pixel electrode 210-1 may be disposed on the fourth organic insulating layer OIL4.

For example, the first auxiliary connection wiring CWL1 may be arranged at (e.g., in or on) the same layer as that of the first auxiliary pixel electrode 210-11, and may include the same material as that of the first auxiliary pixel electrode 210-11. The first auxiliary connection wiring CWL1 may electrically connect the first auxiliary display elements DPE11 to each other. In other words, the first auxiliary connection wiring CWL1 may be integrally provided with the first auxiliary pixel electrode 210-11. Similarly, the second auxiliary connection wiring CWL2 may be arranged at (e.g., in or on) the same layer as that of the second auxiliary pixel electrode 210-12, and may include the same material as that of the second auxiliary pixel electrode 210-12. The third auxiliary connection wiring CWL3 may be arranged at (e.g., in or on) the same layer as that of the third auxiliary pixel electrode 210-13, and may include the same material as that of the third auxiliary pixel electrode 210-13. In other words, the second auxiliary connection wiring CWL2 may be integrally provided with the second auxiliary pixel electrode 210-12, and the third auxiliary connection wiring CWL3 may be integrally provided with the third auxiliary pixel electrode 210-13.

By electrically connecting the auxiliary display elements DPE1 to each other using the auxiliary connection wirings CWL that are arranged at (e.g., in or on) the same layer as that of the auxiliary pixel electrode 210-1, and include the same material as that of the auxiliary pixel electrode 210-1, the number of masks used in a manufacturing process of the display apparatus may be reduced. Accordingly, the manufacturing process of the display apparatus may be simplified. Further, by including the intermediate connection wiring CWLM that is arranged at (e.g., in or on) the same layer as that of the intermediate pixel electrode 210-2, and includes the same material as that of the intermediate pixel electrode 210-2, the manufacturing process of the display apparatus may be simplified.

As described above, when the auxiliary connection wiring CWL is arranged at (e.g., in or on) the same layer as that of the auxiliary pixel electrode 210-1, and includes the same material as that of the auxiliary pixel electrode 210-1, the auxiliary connection wiring CWL may be integrally provided with the auxiliary pixel electrode 210-1. In this case, one end of the auxiliary connection wiring CWL may be in contact with one end of one auxiliary pixel electrode 210-1, and the other end of the auxiliary connection wiring CWL may be in contact with one end of another auxiliary pixel electrode 210-1. Accordingly, the auxiliary connection wiring CWL may electrically connect the auxiliary display elements DPE1 to each other. In other words, the auxiliary connection wiring CWL may electrically connect the auxiliary pixel electrodes 210-1 to each other. However, the present disclosure is not limited thereto, and the auxiliary connection wiring CWL and the auxiliary pixel electrodes 210-1 may be electrically connected to each other through a separate wiring. As described above with reference to FIG. 7, each of the auxiliary connection wirings CWL may be electrically connected to one corresponding wiring WL. For example, four first auxiliary pixel electrodes 210-11 may be electrically connected to one auxiliary pixel circuit PC1 by the first auxiliary connection wiring CWL1. Similarly, two second auxiliary pixel electrodes 210-12 may be electrically connected to another auxiliary pixel circuit PC1 by the second auxiliary connection wiring CWL2, and two third auxiliary pixel electrodes 210-13 may be electrically connected to yet another auxiliary pixel circuit PC1 by the third auxiliary connection wiring CWL3.

As described above, the auxiliary connection wiring CWL may be arranged in the first auxiliary pixel area PXA11, the second auxiliary pixel area PXA12, or the third auxiliary pixel area PXA13. The auxiliary connection wiring CWL may extend from the first auxiliary pixel area PXA11, the second auxiliary pixel area PXA12, or the third auxiliary pixel area PXA13 to the transmission area TA. Accordingly, the auxiliary connection wiring CWL may also be arranged at (e.g., in or on) the transmission area TA. In other words, a portion of the auxiliary connection wiring CWL may be arranged at (e.g., in or on) the transmission area TA.

As described above, the pixel-defining layer 215 may be disposed on the organic insulating layer OIL. In more detail, at (e.g., in or on) the auxiliary display area DA1, the pixel-defining layer 215 may be arranged in the first auxiliary pixel area PXA11, the second auxiliary pixel area PXA12, and the third auxiliary pixel area PXA13. The pixel-defining layer 215 may include a plurality of auxiliary openings 2150P-1. The plurality of auxiliary openings 2150P-1 may include a first auxiliary opening 215OP-11, a second auxiliary opening 215OP-12, and a third auxiliary opening 215OP-13. The first auxiliary opening 215OP-11 may be arranged in the first auxiliary pixel area PXA11, the second auxiliary opening 215OP-12 may be arranged in the second auxiliary pixel area PXA12, and the third auxiliary opening 215OP-13 may be arranged in the third auxiliary pixel area PXA13. Accordingly, the first auxiliary opening 215OP-11 may expose a central portion of the first auxiliary pixel electrode 210-11, the second auxiliary opening 215OP-12 may expose a central portion of the second auxiliary pixel electrode 210-12, and the third auxiliary opening 2150P-13 may expose a central portion of the third auxiliary pixel electrode 210-13.

The first auxiliary opening 2150P-11 and the second auxiliary opening 2150P-12 may be arranged to be adjacent to each other in the first direction D1 (e.g., the direction between the −x direction and the +y direction), and the first auxiliary opening 2150P-11 and the third auxiliary opening 2150P-13 may be arranged to be adjacent to each other in the second direction D2 (e.g., the direction between the −x direction and the −y direction) crossing the first direction D1. As shown in FIG. 8, the first auxiliary opening 215OP-11, the second auxiliary opening 215OP-12, and the third auxiliary opening 215OP-13 may have the same or substantially the same size or similar sizes as each other. As another example, in another embodiment, the first auxiliary opening 2150P-11, the second auxiliary opening 215OP-12, and the third auxiliary opening 2150P-13 may have different sizes from one another.

The auxiliary emission layers 220-1 that emit light may be arranged in the first auxiliary opening 215OP-11, the second auxiliary opening 215OP-12, and the third auxiliary opening 215OP-13, respectively, of the pixel-defining layer 215 (e.g., see FIG. 7). The opposite electrode 230 may be disposed on the auxiliary emission layers 220-1. A stacked structure of the auxiliary pixel electrode 210-1, the auxiliary emission layer 220-1, and the opposite electrode 230 may form one auxiliary display element DPE1. One auxiliary opening 2150P-1 of the pixel-defining layer 215 may correspond to one auxiliary display element DPE1, and may define one emission area.

For example, an emission layer that emits green light may be arranged in the first auxiliary opening 215OP-11, and an emission area defined by the first auxiliary opening 215OP-11 may be defined as the first auxiliary pixel PX11. An emission layer that emits red light may be arranged in the second auxiliary opening 215OP-12, and an emission area defined by the second auxiliary opening 215OP-12 may be defined as the second auxiliary pixel PX12. An emission layer that emits blue light may be arranged in the third auxiliary opening 215OP-13, and an emission area defined by the third auxiliary opening 2150P-13 may be defined as the third auxiliary pixel PX13. However, the present disclosure is not limited thereto. For example, an emission layer that emits blue light or green light may be arranged in the first auxiliary opening 2150P-11, the second auxiliary opening 2150P-12, and the third auxiliary opening 2150P-13. In this case, the display apparatus 1 may further include a color panel disposed on the display panel 10, and the blue light or the green light emitted from an emission layer of the display panel 10 may be converted into green light, red light, or blue light while passing through the color panel, or may be transmitted therethrough. The organic layer 300 may be disposed on the organic insulating layer OIL.

The organic layer 300 may be disposed at (e.g., in or on) the transmission area TA of the auxiliary display area DA1. In other words, the transmission area TA may be a region of an auxiliary pixel area in which the organic layer 300, rather than the pixel-defining layer 215, is disposed on the organic insulating layer OIL. Because a portion of the auxiliary connection wiring CWL may be arranged at (e.g., in or on) the transmission area TA, the organic layer 300 may be disposed on the portion of the auxiliary connection wiring CWL arranged at (e.g., in or on) the transmission area TA. In more detail, the organic layer 300 may cover the portion of the auxiliary connection wiring CWL arranged at (e.g., in or on) the transmission area TA.

As described above, when viewed (e.g., in a plan view) from the direction perpendicular to or substantially perpendicular to the substrate 100 (e.g., in the z-axis direction), the transmission area TA may surround (e.g., around peripheries of) the first auxiliary pixel area PXA11, the second auxiliary pixel area PXA12, and the third auxiliary pixel area PXA13. Accordingly, the organic layer 300 may surround (e.g., around a periphery of) a portion of the pixel-defining layer 215 that defines the first auxiliary opening 2150P-11. Similarly, the organic layer 300 may surround (e.g., around a periphery of) a portion of the pixel-defining layer 215 that defines the second auxiliary opening 2150P-12, and may surround (e.g., around a periphery of) a portion of the pixel-defining layer 215 that defines the third auxiliary opening 215OP-13. In other words, the organic layer 300 may have a mesh shape. Accordingly, a portion of the pixel-defining layer 215 arranged in the first auxiliary pixel area PXA11, the second auxiliary pixel area PXA12, or the third auxiliary pixel area PXA13 may have a ring shape.

Although FIG. 8 shows that the transmission area TA entirely surrounds (e.g., around peripheries of) the first auxiliary pixel area PXA11, the second auxiliary pixel area PXA12, and the third auxiliary pixel area PXA13, the present disclosure is not limited thereto. For example, the transmission area TA may partially surround (e.g., around a periphery of) each of the first auxiliary pixel area PXA11, the second auxiliary pixel area PXA12, and the third auxiliary pixel area PXA13. In other words, the organic layer 300 may partially surround (e.g., around a periphery of) each of the portion of the pixel-defining layer 215 that defines the first auxiliary opening 215OP-11, the portion of the pixel-defining layer 215 that defines the second auxiliary opening 215OP-12, and the portion of the pixel-defining layer 215 that defines the third auxiliary opening 2150P-13.

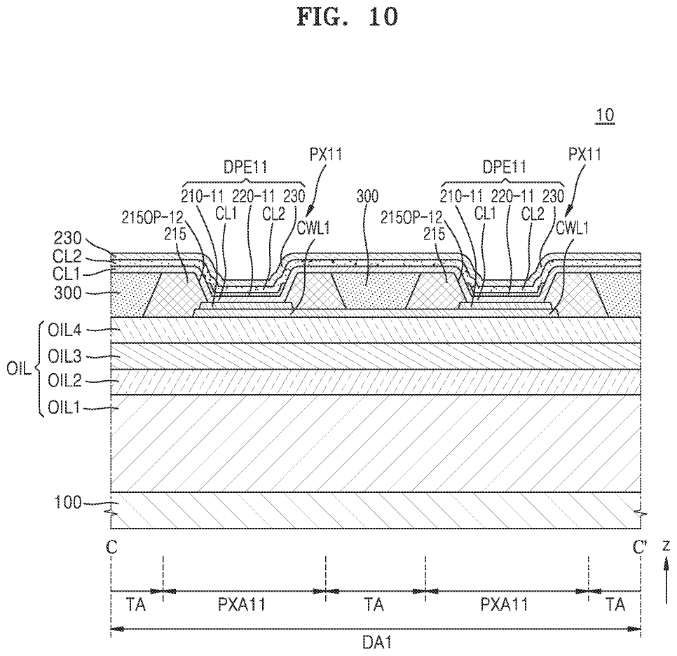

FIG. 9 is a schematic cross-sectional view of a portion of the display panel of the display apparatus 1 according to an embodiment. FIG. 10 is a schematic cross-sectional view of a portion of the display panel 10 of the display apparatus 1 according to an embodiment. In FIGS. 9 and 10, the encapsulation layer ENL, the touch sensor layer TSL, and the optical functional layer OFL are omitted for convenience of illustration.

In more detail, FIG. 9 is a schematic cross-sectional view of the display panel 10 taken along the line B-B′ of FIG. 8, and FIG. 10 is a schematic cross-sectional view of the display panel 10 taken along the line C-C′ of FIG. 8. In FIGS. 9 and 10, the same reference numerals are used to denote the same or substantially the same members as those described above with reference to FIGS. 7 and 8, and thus, redundant description thereof may not be repeated.

Referring to FIG. 9, the organic insulating layer OIL may be disposed on the substrate 100 at (e.g., in or on) the auxiliary display area DA1. In more detail, at (e.g., in or on) the auxiliary display area DA1, the organic insulating layer OIL of the insulating layer IL may be disposed on the substrate 100, but the inorganic insulating layer IIL of the insulating layer IL may not be arranged between the substrate 100 and the organic insulating layer OIL. As described above, the organic insulating layer OIL may include the first organic insulating layer OIL1, the second organic insulating layer OIL2, the third organic insulating layer OIL3, and the fourth organic insulating layer OIL4.

The auxiliary connection wiring CWL may be disposed on the organic insulating layer OIL. The auxiliary connection wiring CWL may be arranged in the first auxiliary pixel area PXA11, the second auxiliary pixel area PXA12, or the third auxiliary pixel area PXA13. In more detail, the first auxiliary connection wiring CWL1 may be disposed on the organic insulating layer OIL in the first auxiliary pixel area PXA11, the second auxiliary connection wiring CWL2 may be disposed on the organic insulating layer OIL in the second auxiliary pixel area PXA12, and the third auxiliary connection wiring CWL3 may be disposed on the organic insulating layer OIL in the third auxiliary pixel area PXA13.

As described above with reference to FIG. 8, the auxiliary connection wiring CWL may also be arranged at (e.g., in or on) the transmission area TA. As shown in FIG. 9, the auxiliary connection wiring CWL may also be arranged at (e.g., in or on) a portion of the transmission area TA arranged between the first auxiliary pixel area PXA11 and the second auxiliary pixel area PXA12. The auxiliary connection wiring CWL arranged at (e.g., in or on) the portion of the transmission area TA may be the third auxiliary connection wiring CWL3. As shown in FIG. 10, the auxiliary connection wiring CWL may also be arranged at (e.g., in or on) another portion of the transmission area TA arranged between the first auxiliary pixel areas PXA11. The auxiliary connection wiring CWL arranged at (e.g., in or on) the other portion of the transmission area TA may be the first auxiliary connection wiring CWL1.

The pixel-defining layer 215 may be disposed on the organic insulating layer OIL. In more detail, the pixel-defining layer 215 may be disposed on the organic insulating layer OIL in the first auxiliary pixel area PXA11, the second auxiliary pixel area PXA12, and the third auxiliary pixel area PXA13, but the pixel-defining layer 215 may not be disposed on the organic insulating layer OIL at (e.g., in or on) the transmission area TA. As described above, the pixel-defining layer 215 may include a light-blocking material.

According to the present embodiment, the pixel-defining layer 215 including a light-blocking material may not be disposed on the organic insulating layer OIL at (e.g., in or on) the transmission area TA of the auxiliary display area DA1. Accordingly, in this case, compared to a case in which the pixel-defining layer 215 including a light-blocking material is also disposed on the organic insulating layer OIL at (e.g., in or on) the transmission area TA of the auxiliary display area DA1, the light transmittance of the display panel 10 may be improved.

The organic layer 300 may be disposed on the organic insulating layer OIL at (e.g., in or on) the transmission area TA. As described above, the organic layer 300 may include a transparent organic insulating material, and may not include a light-blocking material. As described above, a portion of the auxiliary connection wiring CWL may also be arranged at (e.g., in or on) the transmission area TA, and the organic layer 300 may be disposed on the auxiliary connection wiring CWL. In other words, the organic layer 300 may be disposed on the portion of the auxiliary connection wiring CWL arranged at (e.g., in or on) the transmission area TA. In other words, the organic layer 300 may cover the portion of the auxiliary connection wiring CWL arranged at (e.g., in or on) the transmission area TA.

As described above, because the opposite electrode 230 is formed to cover the entire or substantially the entire display area, the opposite electrode 230 may be arranged in the first auxiliary pixel area PXA11, the second auxiliary pixel area PXA12, and the third auxiliary pixel area PXA13. In more detail, in the first auxiliary pixel area PXA11, the second auxiliary pixel area PXA12, and the third auxiliary pixel area PXA13 of the auxiliary display area DA1, the opposite electrode 230 may be disposed on the first auxiliary pixel electrode 210-11, the second auxiliary pixel electrode 210-12, and the third auxiliary pixel electrode 210-13, respectively. The opposite electrode 230 may also be disposed on the pixel-defining layer 215. The opposite electrode 230 may also be arranged at (e.g., in or on) the transmission area TA, and may be disposed on the organic layer 300 at (e.g., in or on) the transmission area TA.

The auxiliary emission layers 220-1 may be arranged between the auxiliary pixel electrodes 210-1 and the opposite electrode 230. In more detail, a first auxiliary emission layer 220-11 may be arranged between the first auxiliary pixel electrode 210-11 and the opposite electrode 230. A second auxiliary emission layer 220-12 may be arranged between the second auxiliary pixel electrode 210-12 and the opposite electrode 230, and a third auxiliary emission layer 220-13 may be arranged between the third auxiliary pixel electrode 210-13 and the opposite electrode 230. In an embodiment, the first auxiliary emission layer 220-11 may emit green light, the second auxiliary emission layer 220-12 may emit red light, and the third auxiliary emission layer 220-13 may emit blue light.

Because the first common layer CL1 and the second common layer CL2 are also formed to cover the entire or substantially the entire display area, the first common layer CL1 and the second common layer CL2 may be arranged in the first auxiliary pixel area PXA11, the second auxiliary pixel area PXA12, and the third auxiliary pixel area PXA13. In the first auxiliary pixel area PXA11, the second auxiliary pixel area PXA12, and the third auxiliary pixel area PXA13, the first common layer CL1 and the second common layer CL2 may be arranged between the first auxiliary pixel electrode 210-11 and the opposite electrode 230, between the second auxiliary pixel electrode 210-12 and the opposite electrode 230, and between the third auxiliary pixel electrode 210-13 and the opposite electrode 230, respectively.

In more detail, in the first auxiliary pixel area PXA11, the second auxiliary pixel area PXA12, and the third auxiliary pixel area PXA13, the first common layer CL1 may be arranged between the first auxiliary pixel electrode 210-11 and the first auxiliary emission layer 220-11, between the second auxiliary pixel electrode 210-12 and the second auxiliary emission layer 220-12, and between the third auxiliary pixel electrode 210-13 and the third auxiliary emission layer 220-13, respectively. In the first auxiliary pixel area PXA11, the second auxiliary pixel area PXA12, and the third auxiliary pixel area PXA13, the second common layer CL2 may be arranged between the first auxiliary emission layer 220-11 and the opposite electrode 230, between the second auxiliary emission layer 220-12 and the opposite electrode 230, and between the third auxiliary emission layer 220-13 and the opposite electrode 230, respectively. The first common layer CL1 and the second common layer CL2 may also be disposed on the pixel-defining layer 215.

The first common layer CL1 and the second common layer CL2 may also be arranged at (e.g., in or on) the transmission area TA, and may be disposed on the organic layer 300 at (e.g., in or on) the transmission area TA. In other words, the first common layer CL1 and the second common layer CL2 may be arranged between the organic layer 300 and the opposite electrode 230 at (e.g., in or on) the transmission area TA. In more detail, at (e.g., in or on) the transmission area TA, the first common layer CL1 may be disposed on the organic layer 300, and the second common layer CL2 may be disposed on the first common layer CL1.

When the organic layer 300 is not disposed on the organic insulating layer OIL at (e.g., in or on) the transmission area TA, leakage current may flow between the auxiliary display elements DPE1. In more detail, when the organic layer 300 is not disposed on the organic insulating layer OIL at (e.g., in or on) the transmission area TA, the auxiliary connection wiring CWL may be in contact with the first common layer CL1. As described above, the first common layer CL1 and the second common layer CL2 may be layers that are integrally formed over the plurality of auxiliary display elements DPE1. Leakage current may flow between the auxiliary display elements DPE1 through these layers.

For example, the third auxiliary connection wiring CWL3 may be arranged at (e.g., in or on) a portion of the transmission area TA between the first auxiliary pixel area PXA11 and the second auxiliary pixel area PXA12, as shown in FIG. 9, but the organic layer 300 may not be disposed on the organic insulating layer OIL at (e.g., in or on) the transmission area TA. In this case, the third auxiliary connection wiring CWL3 may be in contact with the first common layer CL1. Therefore, even when current is to be supplied only to the first auxiliary display element DPE11 that emits green light, current may also be transmitted to the third auxiliary connection wiring CWL3 through the first common layer CL1 and/or the second common layer CL2. Accordingly, current may also be supplied to the third auxiliary display element DPE13 that is electrically connected to the third auxiliary connection wiring CWL3. As a result, because green light is emitted from the first auxiliary display element DPE11, and also, blue light is emitted from the third auxiliary display element DPE13, display quality, for example, such as color purity, may be degraded.

Also, when the organic layer 300 is not disposed on the organic insulating layer OIL at (e.g., in or on) the transmission area TA, the auxiliary pixel electrode 210-1 of the auxiliary display element DPE1 may be electrically connected to the opposite electrode 230, thereby causing a short. For example, the first auxiliary connection wiring CWL1 may be arranged at (e.g., in or on) a portion of the transmission area TA between the first auxiliary pixel areas PXA11, as shown in FIG. 10, but the organic layer 300 may not be disposed on the organic insulating layer OIL at (e.g., in or on) the transmission area TA. In this case, the first auxiliary connection wiring CWL1 at (e.g., in or on) the portion of the transmission area TA may be in contact with the first common layer CL1. The first common layer CL1 at (e.g., in or on) the portion of the transmission area TA may be in contact with the second common layer CL2, and the second common layer CL2 at (e.g., in or on) the portion of the transmission area TA may be in contact with the opposite electrode 230. Accordingly, current may be transmitted from the first auxiliary connection wiring CWL1 at (e.g., in or on) the portion of the transmission area TA to the opposite electrode 230 through the first common layer CL1 and the second common layer CL2. Accordingly, a short may occur between the first auxiliary pixel electrode 210-11 of the first auxiliary display element DPE11 and the opposite electrode 230.

However, according to one or more embodiments of present disclosure, the organic layer 300 may be disposed on the organic insulating layer OIL at (e.g., in or on) the transmission area TA. In other words, the organic layer 300 may cover the portion of the auxiliary connection wiring CWL arranged at (e.g., in or on) the transmission area TA. Therefore, the auxiliary connection wiring CWL may not be in contact with the first common layer CL1. Accordingly, leakage current may not flow between the auxiliary display elements DPE1, and the auxiliary pixel electrode 210-1 of the auxiliary display element DPE1 may not be electrically connected to the opposite electrode 230. In other words, an electrical signal may be effectively transmitted to a display element.

For example, the intermediate pixel electrode 210-2 of the intermediate display element DPE2 may be electrically connected to the intermediate connection wiring CWLM, and the intermediate connection wiring CWLM may be electrically connected to the third connection electrode CM3 through a contact hole formed in (e.g., penetrating) the fourth organic insulating layer OIL4. The display apparatus 1 has been described in detail above, but the present disclosure is not limited thereto, and a method of manufacturing the display apparatus 1 also falls within the spirit and scope of the present disclosure. Hereinafter, the method of manufacturing the display apparatus 1 is described in more detail.

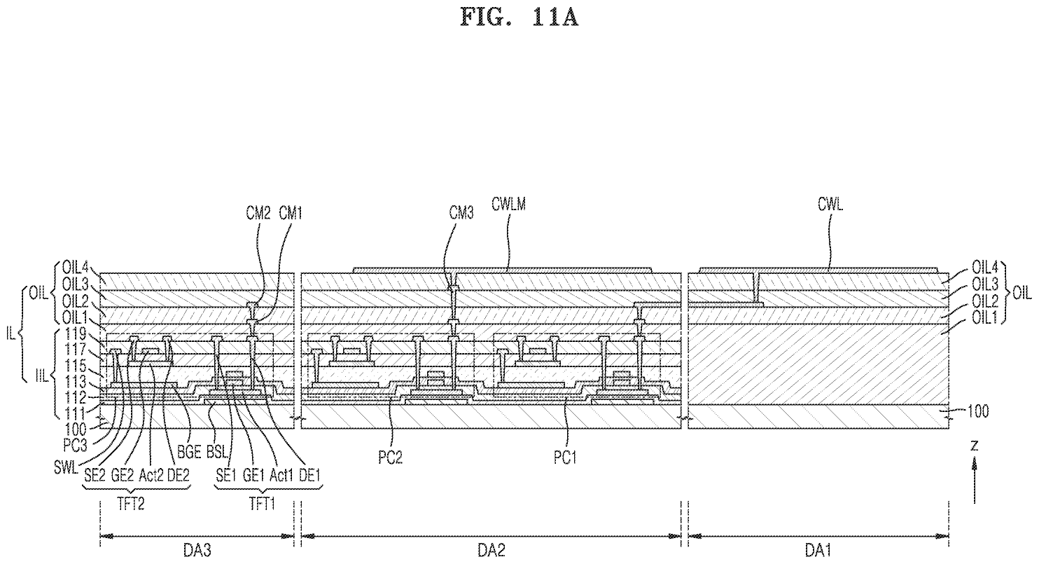

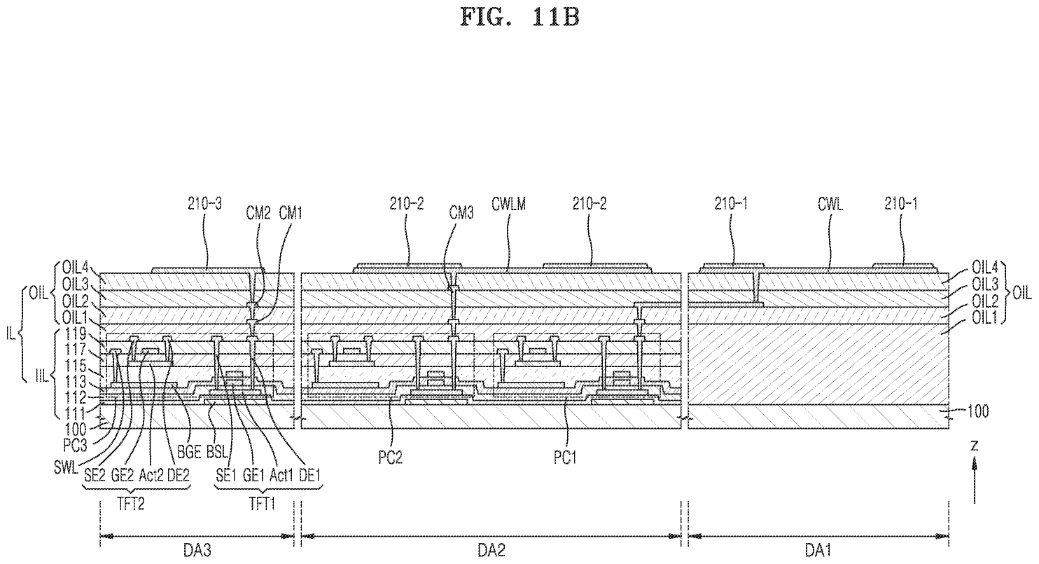

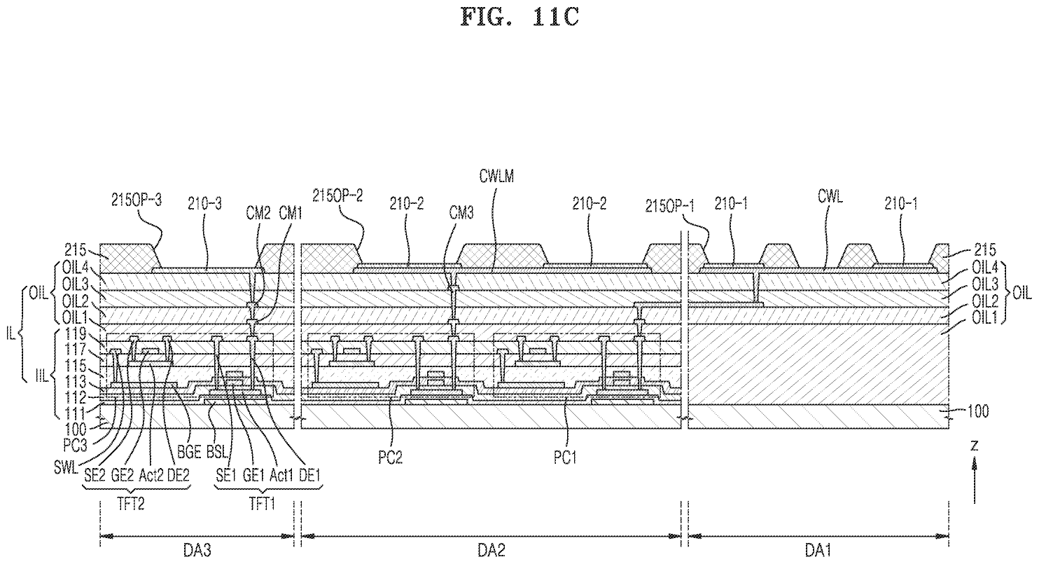

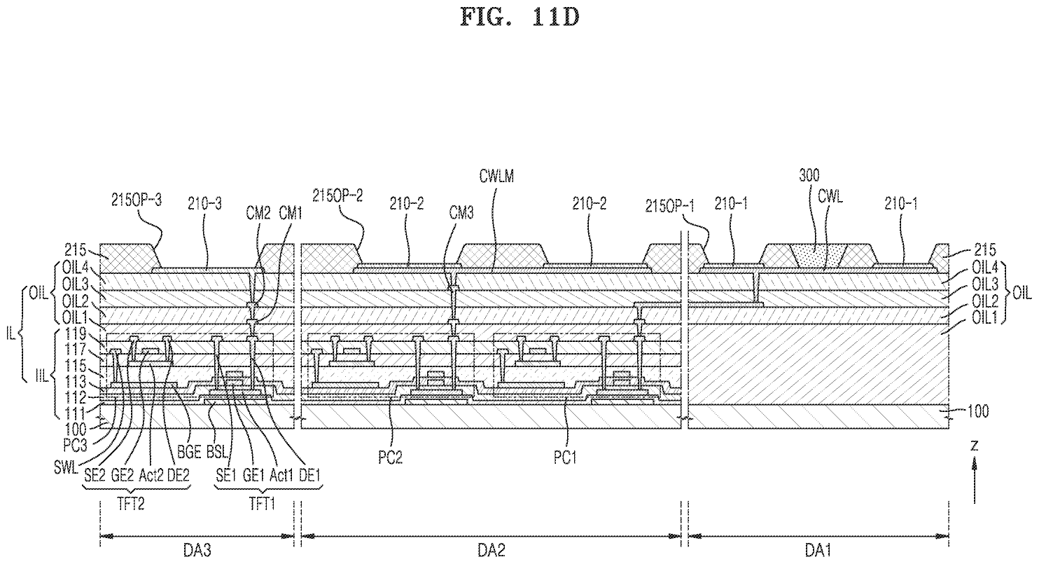

FIGS. 11A through 11D are schematic cross-sectional views showing parts of a manufacturing process of the display panel 10 illustrated in FIG. 8. In more detail, FIGS. 11A through 11D are schematic cross-sectional views showing processes of forming the auxiliary connection wiring CWL, the auxiliary pixel electrode 210-1, the pixel-defining layer 215, and the organic layer 300 included in the display panel 10 illustrated in FIG. 8.

Referring to FIG. 11A, the auxiliary connection wiring CWL may be formed on the organic insulating layer OIL disposed on the substrate 100. Concurrently (e.g., at the same or substantially the same time), the intermediate connection wiring CWLM may be formed on the organic insulating layer OIL. In more detail, the auxiliary connection wiring CWL may be formed on the fourth organic insulating layer OIL4 at (e.g., in or on) the auxiliary display area DA1, and the intermediate connection wiring CWLM may be formed on the fourth organic insulating layer OIL4 at (e.g., in or on) the intermediate display area DA2. The auxiliary connection wiring CWL and the intermediate connection wiring CWLM may be concurrently (e.g., simultaneously or substantially simultaneously) formed with each other of the same material. For example, after forming contact holes in the third organic insulating layer OIL3 and the fourth organic insulating layer OIL4, an auxiliary connection wiring forming material may be deposited on the entire or substantially the entire surface of the substrate 100 by using a sputtering method and/or the like. Thereafter, the auxiliary connection wiring CWL and the intermediate connection wiring CWLM may be formed by patterning the shape of the auxiliary connection wiring CWL and the shape of the intermediate connection wiring CWLM.

The auxiliary connection wiring forming material may include an oxide semiconductor. For example, the oxide semiconductor may include a Zn oxide-based material, such as Zn oxide, In—Zn oxide, or Ga—In—Zn oxide. As another example, the oxide semiconductor may include an IGZO, ITZO, or IGTZO semiconductor containing a metal, such as In, Ga, or Sn, in ZnO.

Referring to FIG. 11B, the auxiliary pixel electrode 210-1 may be formed on the auxiliary connection wiring CWL. Concurrently (e.g., at the same or substantially the same time), the intermediate pixel electrode 210-2 may be formed on the intermediate connection wiring CWLM, and the main pixel electrode 210-3 may be formed on the organic insulating layer OIL. In more detail, the auxiliary pixel electrode 210-1 may be formed on the auxiliary connection wiring CWL at (e.g., in or on) the auxiliary display area DA1, the intermediate pixel electrode 210-2 may be formed on the intermediate connection wiring CWLM at (e.g., in or on) the intermediate display area DA2, and the main pixel electrode 210-3 may be formed on the organic insulating layer OIL at (e.g., in or on) the main display area DA3. The auxiliary pixel electrode 210-1, the intermediate pixel electrode 210-2, and the main pixel electrode 210-3 may be concurrently (e.g., simultaneously or substantially simultaneously) formed with each other of the same material. For example, after forming contact holes in the third organic insulating layer OIL3 and the fourth organic insulating layer OIL4, an auxiliary pixel electrode forming material may be deposited on the entire or substantially the entire surface of the substrate 100 by using a sputtering method and/or the like. Thereafter, the auxiliary pixel electrode 210-1, the intermediate pixel electrode 210-2, and the main pixel electrode 210-3 may be formed by patterning the shape of the auxiliary pixel electrode 210-1, the shape of the intermediate pixel electrode 210-2, and the shape of the main pixel electrode 210-3.

The auxiliary pixel electrode forming material may include a conductive oxide, such as ITO, IZO, ZnO, In₂O₃, IGO, or AZO.

Referring to FIG. 11C, the pixel-defining layer 215 may be formed on the organic insulating layer OIL. In more detail, the pixel-defining layer 215 may be formed to define the auxiliary opening 2150P-1, the intermediate opening 2150P-2, and the main opening 2150P-3. The auxiliary opening 2150P-1 may be arranged at (e.g., in or on) the auxiliary display area DA1 to expose a central portion of the auxiliary pixel electrode 210-1. The intermediate opening 2150P-2 may be arranged at (e.g., in or on) the intermediate display area DA2 to expose a central portion of the intermediate pixel electrode 210-2. The main opening 2150P-3 may be arranged at (e.g., in or on) the main display area DA3 to expose a central portion of the main pixel electrode 210-3.

The pixel-defining layer 215 may include a light-blocking material. The light-blocking material may include at least one of a black pigment, a black dye, or black particles. For example, the light-blocking material may include at least one of Cr, CrOₓ, or CrNₓ, or may include a resin, graphite, a non-Cr-based pigment, a lactam-based pigment, or a perylene-based pigment. The black pigment may include at least one of aniline black, lactam black, or perylene black.

The pixel-defining layer 215 may not be formed at (e.g., in or on) a portion of the auxiliary display area DA1. For example, the pixel-defining layer 215 may not be formed at (e.g., in or on) a portion of the auxiliary display area DA1 in which the auxiliary pixel electrode 210-1 is not formed. Because the pixel-defining layer 215 including the light-blocking material is not formed at (e.g., in or on) the portion of the auxiliary display area DA1, the light transmittance of the display panel 10 may be improved.

Referring to FIG. 11D, the organic layer 300 may be formed on the organic insulating layer OIL. In more detail, the organic layer 300 may be formed on the organic insulating layer OIL at (e.g., in or on) the portion of the auxiliary display area DA1 in which the pixel-defining layer 215 is not formed. The organic layer 300 may include a transparent organic insulating material. For example, the organic layer 300 may include a polymer-based material. The polymer-based material may be transparent. For example, the organic layer 300 may include at least one of a silicone-based resin, an acrylic resin, an epoxy-based resin, polyimide, HMDSO, or polyethylene.

The organic layer 300 may cover a portion of the auxiliary connection wiring CWL that is not covered by the pixel-defining layer 215. Accordingly, even when the first common layer CL1, the second common layer CL2, and the opposite electrode 230 are formed on the auxiliary connection wiring CWL, leakage current may not flow between the auxiliary display elements DPE1, and a short may not occur.

According to the one or more embodiments of the present disclosure, a display apparatus that has high transmittance, and in which an electrical signal may be effectively transmitted to a display element thereof may be implemented. However, the aspects and features of the present disclosure are not limited thereto.

Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display apparatus comprising:
a substrate comprising:
a first auxiliary pixel area;
a second auxiliary pixel area adjacent to the first auxiliary pixel area in a first direction;
a third auxiliary pixel area adjacent to the first auxiliary pixel area in a second direction crossing the first direction; and
a transmission area between the first auxiliary pixel area and the second auxiliary pixel area, and between the first auxiliary pixel area and the third auxiliary pixel area;
a pixel-defining layer comprising:
a first auxiliary opening in the first auxiliary pixel area to expose a central portion of a first auxiliary pixel electrode under the pixel-defining layer;
a second auxiliary opening in the second auxiliary pixel area to expose a central portion of a second auxiliary pixel electrode under the pixel-defining layer; and
a third auxiliary opening in the third auxiliary pixel area to expose a central portion of a third auxiliary pixel electrode under the pixel-defining layer;
an auxiliary connection wiring under the first auxiliary pixel electrode, the second auxiliary pixel electrode, or the third auxiliary pixel electrode, and extending from the first auxiliary pixel area, the second auxiliary pixel area, or the third auxiliary pixel area to the transmission area; and
an organic layer at the transmission area.

2. The display apparatus of claim 1, wherein a portion of the auxiliary connection wiring is located at the transmission area, and
wherein the organic layer is on the portion of the auxiliary connection wiring located at the transmission area.

3. The display apparatus of claim 2, wherein the organic layer covers the portion of the auxiliary connection wiring located at the transmission area.

4. The display apparatus of claim 1, wherein the pixel-defining layer comprises a light-blocking material.

5. The display apparatus of claim 1, wherein the organic layer comprises a transparent organic insulating material, and does not include a light-blocking material.

6. The display apparatus of claim 1, further comprising:
an opposite electrode on the first auxiliary pixel electrode, the second auxiliary pixel electrode, and the third auxiliary pixel electrode;
a first common layer between the first auxiliary pixel electrode and a first auxiliary emission layer, between the second auxiliary pixel electrode and a second auxiliary emission layer, and between the third auxiliary pixel electrode and a third auxiliary emission layer; and
a second common layer between the first auxiliary emission layer and the opposite electrode, between the second auxiliary emission layer and the opposite electrode, and between the third auxiliary emission layer and the opposite electrode.

7. The display apparatus of claim 6, wherein a portion of the opposite electrode, a portion of the first common layer, and a portion of the second common layer are located at the transmission area.

8. The display apparatus of claim 7, wherein the portion of the opposite electrode located at the transmission area is on the organic layer, and the portion of the first common layer located at the transmission area and the portion of the second common layer located at the transmission area are located between the organic layer and the opposite electrode.

9. The display apparatus of claim 1, wherein the transmission area surrounds the first auxiliary pixel area, the second auxiliary pixel area, and the third auxiliary pixel area.

10. The display apparatus of claim 1, wherein:
the auxiliary connection wiring comprises a first auxiliary connection wiring, a second auxiliary connection wiring, and a third auxiliary connection wiring;
the first auxiliary pixel area comprises a plurality of first auxiliary pixel areas;
the second auxiliary pixel area comprises a plurality of second auxiliary pixel areas;
the third auxiliary pixel area comprises a plurality of third auxiliary pixel areas;
the first auxiliary connection wiring electrically connects a plurality of first auxiliary pixel electrodes located at the plurality of first auxiliary pixel areas to each other;
the second auxiliary connection wiring electrically connects a plurality of second auxiliary pixel electrodes located at the plurality of second auxiliary pixel areas to each other; and
the third auxiliary connection wiring electrically connects a plurality of third auxiliary pixel electrodes located at the plurality of third auxiliary pixel areas to each other.

11. The display apparatus of claim 1, further comprising a component overlapping with the first auxiliary pixel area, the second auxiliary pixel area, the third auxiliary pixel area, and the transmission area.

12. A display apparatus comprising:
a substrate comprising a plurality of first auxiliary pixel areas, and a transmission area between the plurality of first auxiliary pixel areas;
a pixel-defining layer having first auxiliary openings located at the plurality of first auxiliary pixel areas to each other to expose central portions of first auxiliary pixel electrodes under the pixel-defining layer;
a first auxiliary connection wiring under the first auxiliary pixel electrodes, and extending to the transmission area; and
an organic layer at the transmission area.

13. The display apparatus of claim 12, wherein a portion of the first auxiliary connection wiring is located at the transmission area, and
wherein the organic layer is on the portion of the first auxiliary connection wiring located at the transmission area.

14. The display apparatus of claim 13, wherein the organic layer covers the portion of the first auxiliary connection wiring located at the transmission area.

15. The display apparatus of claim 12, wherein the pixel-defining layer comprises a light-blocking material.

16. The display apparatus of claim 12, wherein the organic layer comprises a transparent organic insulating material, and does not include a light-blocking material.

17. The display apparatus of claim 12, further comprising:
an opposite electrode on the first auxiliary pixel electrodes;
a first common layer between the first auxiliary pixel electrodes and first auxiliary emission layers; and
a second common layer between the first auxiliary emission layers and the opposite electrode.

18. The display apparatus of claim 17, wherein a portion of the opposite electrode, a portion of the first common layer, and a portion of the second common layer are located at the transmission area.

19. The display apparatus of claim 18, wherein the portion of the opposite electrode located at the transmission area is on the organic layer, and
wherein the portion of the first common layer located at the transmission area and the portion of the second common layer located at the transmission area are between the organic layer and the opposite electrode.

20. The display apparatus of claim 12, wherein the transmission area surrounds each of the plurality of first auxiliary pixel areas.

21. The display apparatus of claim 12, wherein the first auxiliary connection wiring electrically connects the first auxiliary pixel electrodes at the plurality of first auxiliary pixel areas to each other.

22. The display apparatus of claim 12, further comprising a component overlapping with the plurality of first auxiliary pixel areas and the transmission area.
